(19) United States
(12) Patent Application Publication
(10) Pub. No.: US 2024/0290635 A1
(43) Pub. Date: Aug. 29, 2024

(54) SUBSTRATE TREATING METHOD, SUBSTRATE TREATING APPARATUS, TREATMENT LIQUID, AND TREATMENT LIQUID EVALUATION METHOD

(71) Applicant: SCREEN Holdings Co., Ltd., Kyoto (JP)

(72) Inventors: Shogo KUNIEDA, Kyoto (JP); Yuta SASAKI, Kyoto (JP); Koki UONAMI, Kyoto (JP); Yosuke HANAWA, Kyoto (JP)

(21) Appl. No.: 18/437,852

(22) Filed: Feb. 9, 2024

(30) Foreign Application Priority Data
Feb. 24, 2023 (JP) 2023-027290

(51) Int. Cl. H01L 21/67; B05C 11/10; B05C 13/02

(52) U.S. Cl. CPC H01L 21/67034; B05C 11/10; B05C 13/02

(57) ABSTRACT

The present invention relates to a substrate treating method, a substrate treating apparatus, a treatment liquid, and a treatment liquid evaluation method. The substrate treating method includes a treatment liquid supply step, a solidified film forming step, and a sublimation step. In the treatment liquid supply step, the treatment liquid is supplied to a substrate. The treatment liquid contains a sublimable substance and a solvent. In the solidified film forming step, the solvent evaporates from the treatment liquid on the substrate. In the solidified film forming step, a solidified film is formed on the substrate. The solidified film contains the sublimable substance. In the sublimation step, the solidified film sublimates. The substrate is dried by sublimation of the solidified film. Here, the sublimable substance has a maximum positive partial charge of 0.22 or more and less than 0.34.

### CROSS-REFERENCE TO RELATED APPLICATIONS

This application claims priority to Japanese Patent Application No. 2023-027290 filed Feb. 24, 2023, the disclosure of which is hereby incorporated herein by reference in its entirety for all purposes.

### BACKGROUND OF THE INVENTION

### Field of the Invention

The present invention relates to a substrate treating method, a substrate treating apparatus, a treatment liquid, and a treatment liquid evaluation method. The substrate is, for example, a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, or a solar cell substrate.

### Description of the Related Art

JP 2021-9988A discloses a substrate treating method for drying substrates. Specifically, the substrate treating method disclosed in JP 2021-9988A includes a treatment liquid supply step, a solidified film forming step, and a sublimation step. In the treatment liquid supply step, a treatment liquid is supplied to a substrate. The treatment liquid contains a solvent and a sublimable substance. In the solidified film forming step, the solvent evaporates, and a solidified film is formed on the substrate. In the sublimation step, the solidified film sublimates. The solidified film changes to gas without being a liquid. According to the substrate treating method disclosed in JP 2021-9988A, the substrate can be appropriately dried.

### SUMMARY OF THE INVENTION

Even with the currently-used substrate treating method, the substrate may not be appropriately dried occasionally. For example, even with the currently-used substrate treating method, a pattern formed on the substrate may collapse. For example, if the pattern is fine, the currently-used substrate treating method may insufficiently suppress collapse of the pattern.

The present invention has been made regarding the state of the art noted above, and its object is to provide a substrate treating method, a substrate treating apparatus, a treatment liquid, and a treatment liquid evaluation method that can appropriately dry substrates.

In order to achieve such an object, the present invention is constituted as stated below. One aspect of the present invention provides a substrate treating method for performing treatment on a substrate on which a pattern is formed. The substrate treating method includes: a treatment liquid supply step of supplying a treatment liquid containing a sublimable substance and a solvent to the substrate; a solidified film forming step of forming a solidified film containing the sublimable substance on the substrate by evaporating the solvent from the treatment liquid on the substrate; and a sublimation step of sublimating the solidified film; and the sublimable substance has a maximum positive partial charge of 0.22 or more and less than 0.34.

The substrate treating method is for treating the substrate on which the pattern is formed. The substrate treating method includes the treatment liquid supply step, the solidified film forming step, and the sublimation step. In the treatment liquid supply step, the treatment liquid is supplied to the substrate. The treatment liquid contains the sublimable substance and the solvent. In the solidified film forming step, the solvent evaporates from the treatment liquid on the substrate. In the solidified film forming step, the solidified film is formed on the substrate. The solidified film contains the sublimable substance. In the sublimation step, the solidified film sublimates. The substrate is dried by sublimation of the solidified film.

Here, the sublimable substance has a maximum positive partial charge of 0.22 or more and less than 0.34. In other words, the sublimable substance satisfies a first condition.

First condition: The sublimable substance has a maximum positive partial charge of 0.22 or more and less than 0.34.

In this specification, the “maximum positive partial charge of the sublimable substance” is defined as a value obtained based on the chemical structure of the sublimable substance using MaxPartialCharge which is a descriptor of RDKit. RDKit is software in the field of chemo-informatics.

Accordingly, in the solidified film forming step, the solidified film is suitably formed on the substrate. Further, in the sublimation step, the solidified film appropriately sublimates. That is, in the sublimation step, the substrate is appropriately dried. Specifically, in the sublimation step, the substrate is dried while the pattern formed on the substrate is suitably protected.

As described above, according to this substrate treating method, the substrate is appropriately dried.

In the substrate treating method described above, the sublimable substance is preferably an organic compound. Accordingly, it is easy for the sublimable substance to satisfy the first condition.

In the substrate treating method described above, the sublimable substance preferably contains a benzene ring. Accordingly, it is easy for the sublimable substance to satisfy the first condition.

Another aspect of the present invention provides a substrate treating apparatus. The substrate treating apparatus includes a substrate holder configured to hold a substrate; and a treatment liquid supply unit configured to supply a treatment liquid containing a sublimable substance and a solvent to the substrate held by the substrate holder; and the sublimable substance has a maximum positive partial charge of 0.22 or more and less than 0.34.

The substrate treating apparatus includes the substrate holder and the treatment liquid supply unit. The substrate holder holds the substrate. The treatment liquid supply unit supplies the treatment liquid to the substrate held by the substrate holder. The treatment liquid contains the sublimable substance and the solvent.

Here, the sublimable substance has a maximum positive partial charge of 0.22 or more and less than 0.34. In other words, the sublimable substance satisfies the first condition described above. Accordingly, the solidified film is suitably formed on the substrate. Furthermore, the solidified film appropriately sublimates. That is, the substrate is appropriately dried. Specifically, the substrate is dried while the pattern formed on the substrate is suitably protected.

As described above, according to this substrate treating apparatus, the substrate is appropriately dried.

Another aspect of the present invention provides a treatment liquid used for drying a substrate on which a pattern is formed. The treatment liquid contains a sublimable substance and a solvent, and the sublimable substance has a maximum positive partial charge of 0.22 or more and less than 0.34.

The treatment liquid is used for drying the substrate on which the pattern is formed. Specifically, the treatment liquid is a dry-assisting liquid. The treatment liquid contains the sublimable substance and the solvent.

Here, the sublimable substance has a maximum positive partial charge of 0.22 or more and less than 0.34. In other words, the sublimable substance satisfies the first condition described above. Accordingly, by supplying the treatment liquid to the substrate, the solidified film is suitably formed on the substrate. Furthermore, the solidified film appropriately sublimates. That is, the substrate is appropriately dried. Specifically, the substrate is dried while the pattern formed on the substrate is suitably protected.

As described above, the substrate is appropriately dried using the treatment liquid. The treatment liquid is useful for drying the substrate.

In the treatment liquid described above, it is preferable that the treatment liquid is supplied to the substrate, the solvent evaporates from the treatment liquid on the substrate, a solidified film containing the sublimable substance is formed on the substrate, and then the solidified film sublimates. When the treatment liquid is used in this way, the substrate is more appropriately dried. When the treatment liquid is used in this way, the treatment liquid is more useful for drying the substrate.

Another aspect of the present invention provides a treatment liquid evaluation method for evaluating a treatment liquid used for drying a substrate on which a pattern is formed. The treatment liquid contains a sublimable substance and a solvent, and the treatment liquid evaluation method includes an evaluation step of evaluating the treatment liquid based on a maximum positive partial charge of the sublimable substance.

The treatment liquid evaluation method is for evaluating the treatment liquid. The treatment liquid is used for drying the substrate on which the pattern is formed. Specifically, the treatment liquid is the dry-assisting liquid. The treatment liquid contains the sublimable substance and the solvent. The treatment liquid evaluation method includes the evaluation step. In the evaluation step, the treatment liquid is evaluated based on the maximum positive partial charge of the sublimable substance. Therefore, the treatment liquid is appropriately evaluated.

As described above, according to this treatment liquid evaluation method, the treatment liquid is appropriately evaluated. This treatment liquid evaluation method is useful for selection of a treatment liquid.

In the treatment liquid evaluation method described above, the treatment liquid evaluation method preferably further includes an acquisition step of acquiring the maximum positive partial charge of the sublimable substance. Accordingly, it is easy to evaluate the treatment liquid based on the maximum positive partial charge of the sublimable substance in the evaluation step.

In the treatment liquid evaluation method described above, in the acquisition step, the maximum positive partial charge of the sublimable substance is preferably obtained based on the chemical structure of the sublimable substance using MaxPartialCharge which is a descriptor of RDKit. Accordingly, in the acquisition step, the maximum positive partial charge of the sublimable substance is appropriately acquired.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a view schematically showing a part of a substrate;

FIG. 2 is a diagram showing a chemical structural formula of N-ethyl-p-toluenesulfonamide;

FIG. 3 is a plan view of an interior of a substrate treating apparatus according to a first embodiment;

FIG. 4 is a control block diagram of the substrate treating apparatus;

FIG. 5 is a diagram showing a construction of a treating unit and a first supply source according to the first embodiment;

FIG. 6 is a flow chart showing procedures of a substrate treating method according to the first embodiment;

FIG. 7 is a view schematically showing a substrate in a treatment liquid supply step;

FIG. 8 is a view schematically showing the substrate in a solidified film forming step;

FIG. 9 is a view schematically showing the substrate in the solidified film forming step;

FIG. 10 is a view schematically showing the substrate in a sublimation step;

FIG. 11 is a view schematically showing the substrate in the sublimation step;

FIG. 12 is a table showing average collapse rates in Examples and Comparative Examples;

FIG. 13 exemplarily shows a mechanism for collapse of a pattern formed on the substrate;

FIG. 14 exemplarily shows the mechanism for collapse of a pattern formed on the substrate;

FIG. 15 exemplarily shows the mechanism for collapse of a pattern formed on the substrate;

FIG. 16 exemplarily shows the mechanism for collapse of a pattern formed on the substrate;

FIG. 17 is a flow chart showing procedures of a treatment liquid evaluation method of a second embodiment; and

FIG. 18 is a diagram showing a construction of a treating unit and a first supply source according to a modified embodiment.

### DETAILED DESCRIPTION

The following describes a substrate treating method, a substrate treating apparatus, a treatment liquid, and a treatment liquid evaluation method of the present invention with reference to the drawings.

### 1. Substrate

A substrate W is, for example, a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, or a solar cell substrate. The substrate W has a thin and flat plate shape. The substrate W has a substantially circular shape in plan view.

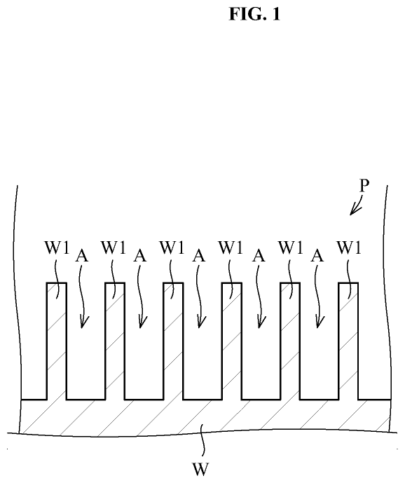

FIG. 1 is a diagram schematically showing a part of the substrate W. The substrate W has a pattern P. The pattern P is formed on the surface of the substrate W.

The pattern P has, for example, an uneven shape. The pattern P includes, for example, projections W1 and recesses A. The projections W1 are part of the substrate W. The projections W1 are a structure. The projections W1 are each formed with, for example, at least one of a silicon oxide (SiO2) film, a silicon nitride (SiN) film, and a polysilicon film. The projections W1 project upward from the surface of the substrate W, for example. The recess A is laterally adjacent to the projection W1. The recess A is a space. The recess A is opened upward, for example. The projection W1 corresponds to a wall defining the recess A.

### 2. Treatment Liquid (Dry-Assisting Liquid)

In this specification, the treatment liquid used for drying the substrate W is simply referred to as a “treatment liquid”. The treatment liquid has a function of assisting drying of the substrate W. The treatment liquid can be rephrased as the dry-assisting liquid.

The treatment liquid contains a sublimable substance. The sublimable substance has sublimability. “Sublimability” means a property that a single substance, a compound or a mixture changes its phase from a solid phase to a gas phase or from a gas phase to a solid phase without passing through a liquid phase.

Here, the sublimable substance satisfies a following first condition M.

First condition M: The sublimable substance has a maximum positive partial charge of 0.22 or more and less than 0.34.

In this specification, the “maximum positive partial charge of the sublimable substance” is defined as a value obtained based on the chemical structure of the sublimable substance using MaxPartialCharge. MaxPartialCharge is one of descriptors included in the RDKit. RDKit is software in the field of chemo-informatics. For RDKit, see, for example, https://www.rdkit.org. When one chemical structure is input to MaxPartialCharge, MaxPartialCharge outputs one value. The chemical structure is also called a two-dimensional structural formula. The value output from MaxPartialCharge is the maximum positive partial charge. As described above, the maximum positive partial charge is uniquely determined by the chemical structure. The unit of the maximum positive partial charge is dimensionless [−]. The maximum positive partial charge takes zero or a positive value and does not take a negative value.

One molecule of the sublimable substance has a plurality of atoms. Each atom contained in the molecule of the sublimable substance has a partial charge [C]. In other words, the molecule of the sublimable substance has a plurality of partial charges [C]. [C] represents a unit of partial charge, i.e. coulomb. Each partial charge [C] in the molecule of the sublimable substance may take a positive value or a negative value. In order to clearly distinguish the “maximum positive partial charge” and the “partial charge”, [C] is added to the latter, and the latter is written as the “partial charge [C]”.

The maximum positive partial charge of the sublimable substance described above is an index indicating the largest partial charge [C] in the molecule of the sublimable substance. As the maximum positive partial charge of the sublimable substance increases, the largest partial charge [C] in the molecule of the sublimable substance increases. Thus, the maximum positive partial charge of the sublimable substance may, for example, be referred to as the “index for the largest partial charge [C] in the molecule of the sublimable substance”.

Furthermore, the sublimable substance is preferably, for example, an organic compound. The sublimable substance preferably contains, for example, a benzene ring.

The sublimable substance is, for example, compound a, b, c, d, e, or f.
Compound a: o-Acetanisidide
Compound b: N-Ethyl-p-toluenesulfonamide
Compound c: 4-Chlorophenylacetic acid
Compound d: 4-Methoxyphenylacetic acid
Compound e: 2-Chlorophenylacetic acid
Compound f: Dimethyl isophthalate

o-Acetanisidide is also called N-(2-Methoxyphenyl) acetamide. N-Ethyl-p-toluenesulfonamide is also called N-ethyl-4-methylbenzenesulfonamide. 4-Chlorophenylacetic acid is also called 2-(4-chlorophenyl) acetic acid. 4-Methoxyphenylacetic acid is also called 2-(4-methoxyphenyl) acetic acid. 2-Chlorophenylacetic acid is also called 2-(2-chlorophenyl) acetic acid. Dimethyl isophthalate is also called dimethyl benzene-1,3-dicarboxylate.

The maximum positive partial charge values of the compounds a to f are shown below. The compound a has a maximum positive partial charge of 0.22. The compound b has a maximum positive partial charge of 0.24. The compound c has a maximum positive partial charge of 0.30. The compound d has a maximum positive partial charge of 0.30. The compound e has a maximum positive partial charge of 0.30. The compound f has a maximum positive partial charge of 0.33.

The above values were obtained based on the chemical structures of the compounds a to f using MaxPartialCharge included in the RDKit. More specifically, the above values were obtained based on the chemical structures of the compounds a to f using MaxPartialCharge included in version 2022.9.4 of the RDKit.

Therefore, the compound a satisfies the first condition M. The compound a is an example of a sublimable substance satisfying the first condition M. Likewise, each of the compounds b to f satisfies the first condition M. The compounds b to f are examples of sublimable substances satisfying the first condition M.

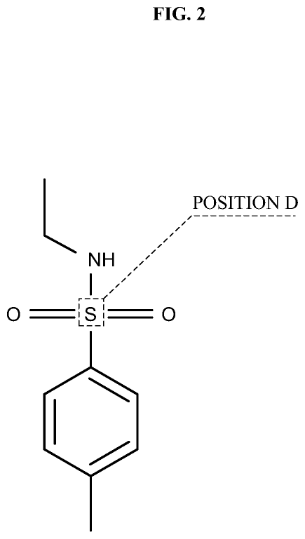

FIG. 2 is a chemical structural formula of the compound b, that is, N-ethyl-p-toluenesulfonamide. One molecule of the compound b has a plurality of atoms. Each atom contained in one molecule of the compound b has a partial charge [C]. That is, one molecule of the compound b has a plurality of partial charges [C]. Among the plurality of partial charges [C] of the compound b, the largest partial charge [C] is a partial charge [C] of sulfur atom “S” at position D. In other words, the sulfur atom “S” at position D has the largest partial charge [C] among the plurality of partial charges [C] of the compound b.

In view of this, the maximum positive partial charge of the compound b corresponds to an index indicating the magnitude of the partial charge [C] of the sulfur atom “S” at position D.

Each of the compounds a to f is an organic compound. Each of the compounds a to f contains a benzene ring.

The sublimable substance contains at least one of the compounds a, b, c, d, e, and f. For example, the sublimable substance contains the compound a. For example, the sublimable substance contains the compound a and the compound b. For example, the sublimable substance contains the compounds a to f.

For example, the sublimable substance consists of only at least one of the compounds a to f. For example, the sublimable substance consists of only the compound a. For example, the sublimable substance consists of only the compound a and the compound b. For example, the sublimable substance consists of only the compounds a to f.

For example, the sublimable substance is at least one of the compounds a to f. For example, the sublimable substance is the compound a. For example, the sublimable substance is the compound a and the compound b. For example, the sublimable substance is the compounds a to f.

The treatment liquid contains a solvent. The solvent dissolves the sublimable substance. The sublimable substance in the treatment liquid is dissolved in the solvent. That is, the treatment liquid contains the solvent and the sublimable substance dissolved in the solvent. The sublimable substance corresponds to a solute of the treatment liquid.

The solvent has a relatively high vapor pressure. The solvent has a relatively high vapor pressure at normal temperatures. For example, the vapor pressure of the solvent at normal temperatures is preferably higher than the vapor pressure of the sublimable substance at normal temperatures.

Here, the normal temperatures include a room temperature. The normal temperatures fall within a temperature range of 5° C. or more and 35° C. or less, for example. The normal temperatures fall within a temperature range of 10° C. or more and 30° C. or less, for example. The normal temperatures fall within a temperature range of 20° C. or more and 25° C. or less, for example.

The solvent is, for example, an organic solvent. The solvent is, for example, an alcohol.

The solvent contains, for example, isopropyl alcohol (IPA). The solvent consists of, for example, only isopropyl alcohol. The solvent is, for example, isopropyl alcohol.

The treatment liquid consists of, for example, only the sublimable substance and the solvent.

The treatment liquid consists of, for example, only the compound a and isopropyl alcohol. The treatment liquid consists of, for example, only the compounds a to f and isopropyl alcohol.

The volume of the sublimable substance contained in the treatment liquid is smaller than the volume of the solvent contained in the treatment liquid. For example, the volume ratio RV of the treatment liquid is preferably 1 [Vol %] or more and 20 [Vol %] or less. Here, the volume ratio RV of the treatment liquid is a ratio of the volume of the sublimable substance contained in the treatment liquid to the volume of the solvent contained in the treatment liquid. In other words, the volume ratio RV of the treatment liquid is defined by the following formula.

RV=(Volume of sublimable substance contained in treatment liquid)/(Volume of solvent contained in treatment liquid)*100 [Vol %]

### 3. Outline of Substrate Treating Apparatus

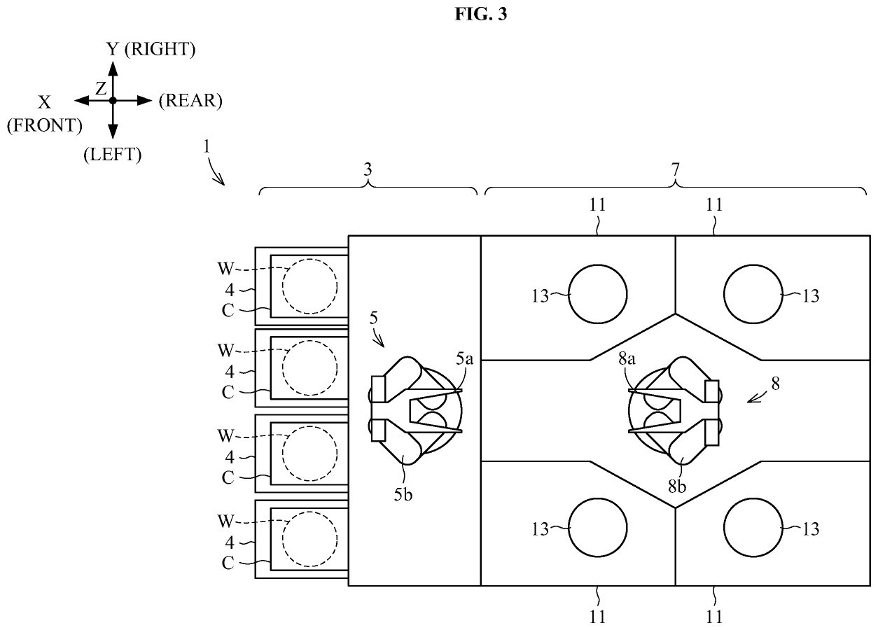

FIG. 3 is a plan view of an interior of a substrate treating apparatus 1 according to the first embodiment. The substrate treating apparatus 1 performs treatment on the substrate W. The treatment in the substrate treating apparatus 1 includes a dry treatment.

The substrate treating apparatus 1 includes an indexer 3 and a treating block 7. The treating block 7 is connected to the indexer 3. The indexer 3 supplies the substrate W to the treating block 7. The treating block 7 performs a treatment on the substrate W. The indexer 3 collects the substrate W from the treating block 7.

In this specification, the direction in which the indexer 3 and the treating block 7 are arranged is referred to as a “front-rear direction X” for convenience. The front-rear direction X is horizontal. One direction of the front-rear direction X from the treating block 7 to the indexer 3 is referred to as a “forward direction”. The direction opposite to the forward direction is referred to as a “rearward direction”. A horizontal direction orthogonal to the front-rear direction X is referred to as a “transverse direction Y”. Moreover, one direction of the transverse direction Y is referred to as a “rightward direction”, as appropriate. The direction opposite to the rightward direction is referred to as a “leftward direction”. The perpendicular direction relative to the horizontal direction is referred to as a “vertical direction Z”. For reference, the drawings show front, rear, right, left, up, and down, as appropriate.

The indexer 3 includes a plurality of (e.g., four) carrier platforms 4. The carrier platforms 4 each include one carrier C placed thereon. The carrier C accommodates a plurality of substrates W. The carrier C is, for example, a front opening unified pod (FOUP), a standard mechanical interface (SMIF), or an open cassette (OC).

The indexer 3 includes a transport mechanism 5. The transport mechanism 5 is arranged rearward of the carrier platforms 4. The transport mechanism 5 transports the substrate W. The transport mechanism 5 is accessible to the carriers C placed on the carrier platforms 4, respectively. The transport mechanism 5 includes a hand 5a and a hand driving unit 5b. The hand 5a supports the substrate W. The hand driving unit 5b is coupled to the hand 5a. The hand driving unit 5b moves the hand 5a. The hand driving unit 5b moves the hand 5a in the front-rear direction X, transverse direction Y, and vertical direction Z, for example. The hand driving unit 5b rotates the hand 5a in a horizontal plane, for example.

The treating block 7 includes a transport mechanism 8. The transport mechanism 8 transports the substrate W. The transport mechanism 5 and the transport mechanism 8 are configured to transfer the substrate W to each other. The transport mechanism 8 includes a hand 8a and a hand driving unit 8b. The hand 8a supports the substrate W. The hand driving unit 8b is coupled to the hand 8a. The hand driving unit 8b moves the hand 8a. The hand driving unit 8b moves the hand 8a in the front-rear direction X, transverse direction Y, and vertical direction Z, for example. The hand driving unit 8b rotates the hand 8a in a horizontal plane, for example.

The treating block 7 includes a plurality of treating units 11. The treating unit 11 is also called a treating chamber 11. The treating units 11 are each arranged laterally of the transport mechanism 8. The treating units 11 each perform a treatment on the substrate W individually.

The treating unit 11 includes a substrate holder 13. The substrate holder 13 is configured to hold the substrate W. The substrate holder 13 includes at least one of a vacuum chuck, a Bernoulli chuck, a chuck pin, and the like. Each of the vacuum chuck and the Bernoulli chuck sucks and holds the substrate W. The vacuum chuck sucks and holds, for example, the center of the substrate W. The Bernoulli chuck also sucks and holds, for example, the center of the substrate W. The chuck pin grips the substrate W. The chuck pin grips, for example, an end surface of the substrate W.

The transport mechanism 8 is accessible to the treating units 11 individually. The transport mechanism 8 can deliver the substrate W to the substrate holder 13. The transport mechanism 8 can take the substrate W from the substrate holder 13.

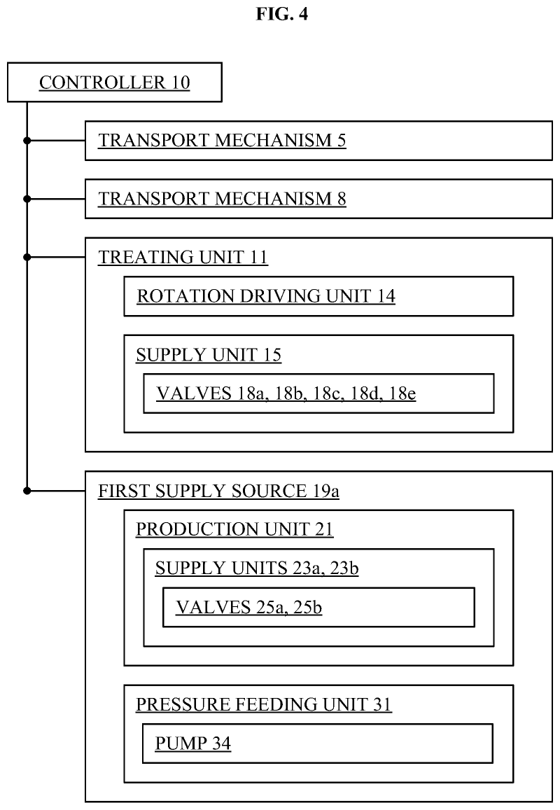

FIG. 4 is a control block diagram of the substrate treating apparatus 1. The substrate treating apparatus 1 includes a controller 10. The controller 10 can communicate with the transport mechanisms 5, 8 and the treating units 11. The controller 10 controls the transport mechanisms 5, 8 and the treating units 11.

The controller 10 is implemented by a central processing unit (CPU) that performs various processes, a random-access memory (RAM) as a workspace of arithmetic processing, and a storage medium such as a fixed disk. The controller 10 contains various types of information stored in the storage medium in advance. The information stored in the controller 10 includes transportation condition information for controlling the transport mechanisms 5, 8, for example. The information stored in the controller 10 includes processing condition information for controlling the treating units 11, for example. The processing condition information is also called processing recipes.

Reference is made to FIG. 3. The following simply describes one example of operation of the substrate treating apparatus 1.

The transport mechanisms 5 and 8 transport the substrate W from the carrier C to the treating unit 11. Specifically, the transport mechanism 5 transports the substrate W out of the carrier C. Then, the transport mechanism 5 transports the substrate W from the carrier C to the transport mechanism 8. The transport mechanism 8 transports the substrate W from the transport mechanism 5 to the treating unit 11. The transport mechanism 8 delivers the substrate W to the substrate holder 13 of the treating unit 11.

The treating unit 11 performs treatment on the substrate W. The treating unit 11 performs treatment on the substrate W held by the substrate holder 13. The treating unit 11 performs a dry treatment, for example, on the substrate W.

After the treating unit 11 performs treatment on the substrate W, the transport mechanisms 5 and 8 transport the substrate W from the treating units 11 to the carrier C. Specifically, the transport mechanism 8 takes the substrate W from the substrate holder 13 of the treating unit 11. The transport mechanism 8 transports the substrate W from the treating unit 11 to the transport mechanism 5. The transport mechanism 5 transports the substrate W from the transport mechanism 8 to the carrier C. The transport mechanism 5 transports the substrate W into the carrier C.

### 4. Construction of Treating Unit 11

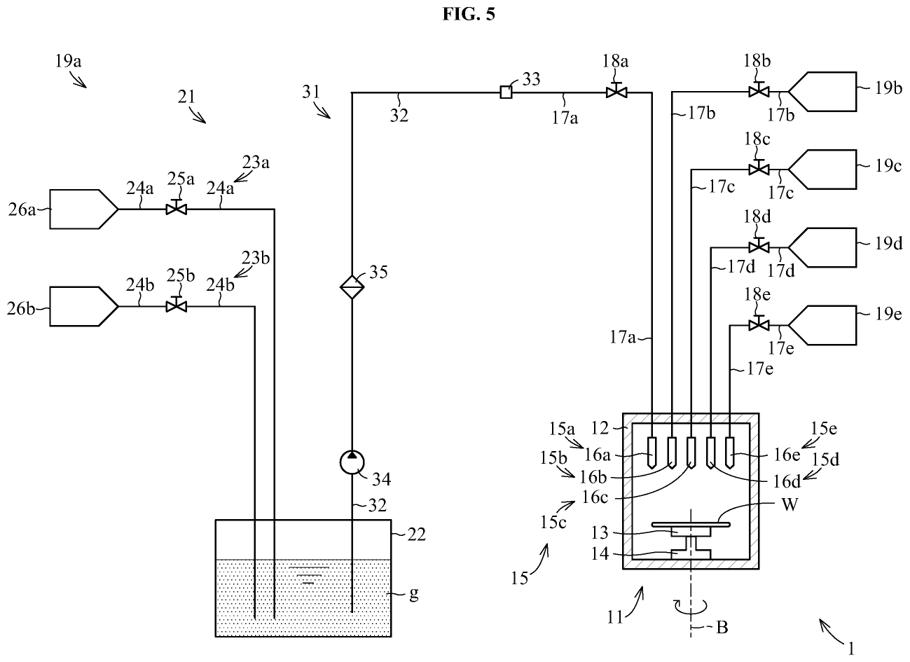

FIG. 5 is a diagram showing a construction of the treating unit 11. The treating units 11 each have the same construction. The treating unit 11 is classified as a single-wafer processing unit. That is, the treating units 11 each perform a treatment on only one substrate W at one time.

The treating unit 11 includes a casing 12. The casing 12 has a substantial box shape. The substrate W is treated within the casing 12.

The interior of the casing 12 is kept at normal temperatures. The temperature of the gas in the interior of the casing 12 is kept at normal temperatures. Accordingly, the substrate W is treated under an environment of normal temperatures.

The interior of the casing 12 is kept at normal pressure. The pressure of the gas in the interior of the casing 12 is kept at normal pressure. Accordingly, the substrate W is treated under an environment of normal pressure.

Here, the normal pressure includes standard atmospheric pressure (1 atm, 101325 Pa). The normal pressure falls within a pressure range of 0.7 to 1.3 atm, for example. In this specification, the value of pressure is indicated as absolute pressure relative to absolute vacuum.

The substrate holder 13 described above is installed in the interior of the casing 12. The substrate holder 13 holds one substrate W. The substrate holder 13 holds the substrate W in a substantially horizontal posture.

The substrate holder 13 is located below the substrate W held by the substrate holder 13. The substrate holder 13 is in contact with at least one of a lower surface of the substrate W and a peripheral edge of the substrate W. The lower surface of the substrate W is also called a back side of the substrate W. The substrate holder 13 is not in contact with an upper surface of the substrate W.

The treating units 11 each include a rotation driving unit 14. At least a part of the rotation driving unit 14 is installed in the interior of the casing 12. The rotation driving unit 14 is connected to the substrate holder 13. The rotation driving unit 14 rotates the substrate holder 13. The substrate W held by the substrate holder 13 rotates integrally with the substrate holder 13. The substrate W held by the substrate holder 13 rotates around a rotation axis B. The rotation axis B passes through the center of the substrate W and extends in the vertical direction Z, for example.

The treating unit 11 includes a supply unit 15. The supply unit 15 supplies a liquid or gas to the substrate W held by the substrate holder 13. Specifically, the supply unit 15 supplies liquid or gas onto the upper surface of the substrate W held by the substrate holder 13.

The supply unit 15 includes a first supply unit 15a, a second supply unit 15b, a third supply unit 15c, a fourth supply unit 15d, and a fifth supply unit 15e. The first supply unit 15a supplies the above-described treatment liquid. The second supply unit 15b supplies a chemical liquid. The third supply unit 15c supplies a rinse liquid. The fourth supply unit 15d supplies a replacement solution. The fifth supply unit 15e supplies a dry gas.

The first supply unit 15a is an example of the treatment liquid supply unit in the present invention.

As described above, the interior of the casing 12 is at normal temperatures and normal pressure. Accordingly, the treatment liquid is used under an environment of normal temperatures. The treatment liquid is used under an environment of normal pressure.

The chemical liquid supplied by the second supply unit 15b is, for example, an etchant. The etchant includes, for example, at least either hydrofluoric acid (HF) or buffered hydrofluoric acid (BHF).

The rinse liquid supplied by the third supply unit 15c is, for example, deionized water (DIW).

The replacement solution supplied by the fourth supply unit 15d is, for example, an organic solvent. The replacement solution is, for example, isopropyl alcohol.

The dry gas supplied by the fifth supply unit 15e is, for example, at least one of air and inert gas. The air is, for example, compressed air. The inert gas is, for example, nitrogen gas. The dry gas preferably has a dew point lower than normal temperatures.

The first supply unit 15a includes a nozzle 16a. Likewise, the second to fifth supply units 15b to 15e include nozzles 16b to 16e, respectively. Each of the nozzles 16a to 16e is installed in the interior of the casing 12. The nozzle 16a dispenses the treatment liquid. The nozzle 16b dispenses the chemical liquid. The nozzle 16c dispenses the rinse liquid. The nozzle 16d dispenses the replacement solution. The nozzle 16e dispenses the dry gas.

The first supply unit 15a includes a pipe 17a and a valve 18a. The pipe 17a is connected to the nozzle 16a. The valve 18a is provided on the pipe 17a. When the valve 18a opens, the nozzle 16a dispenses the treatment liquid. When the valve 18a closes, the nozzle 16a does not dispense the treatment liquid. Likewise, the second to fifth supply units 15b to 15e include pipes 17b to 17e and valves 18b to 18e, respectively. The pipes 17b to 17e are connected to the nozzles 16b to 16e, respectively. The valves 18b to 18e are provided on the pipes 17b to 17e, respectively. The valves 18b to 18e control dispensing of the chemical liquid, the rinse liquid, the replacement solution, and the dry gas, respectively.

At least part of the pipe 17a may be provided externally of the casing 12. The same arrangement of the pipe 17a is applicable to arrangement of the pipes 17b to 17e. The valve 18a may be provided externally of the casing 12. The same arrangement of the valve 18a is applicable to arrangement of the valves 18b to 18e.

The substrate treating apparatus 1 includes a first supply source 19a. The first supply source 19a is connected to the first supply unit 15a. The first supply source 19a is connected to, for example, the pipe 17a. The first supply source 19a is in fluid communication with the first supply unit 15a. The first supply source 19a feeds the treatment liquid to the first supply unit 15a.

The second supply unit 15b is connected to the second supply source 19b. For example, the pipe 17b is connected to the second supply source 19b. The second supply unit 15b is in fluid communication with the second supply source 19b. The second supply source 19b feeds the chemical liquid to the second supply unit 15b. Likewise, the third to fifth supply units 15c to 15e are connected to the third to fifth supply sources 19c to 19e, respectively. For example, the pipes 17c to 17e are connected to the third to fifth supply sources 19c to 19e, respectively. The third to fifth supply units 15c to 15e are in fluid communication with the third to fifth supply sources 19c to 19e, respectively. The third supply source 19c feeds the rinse liquid to the third supply unit 15c. The fourth supply source 19d feeds the replacement solution to the fourth supply unit 15d. The fifth supply source 19e feeds the dry gas to the fifth supply unit 15e.

The first supply source 19a is provided externally of the casing 12. Likewise, each of the second to fifth supply sources 19b to 19e is provided externally of the casing 12.

The first supply source 19a may supply the treatment liquid to the plurality of treating units 11. Alternatively, the first supply source 19a may supply the treatment liquid to only one treating unit 11. The same applies to the second to fifth supply sources 19b to 19e.

The second supply source 19b may be an element of the substrate treating apparatus 1. For example, the second supply source 19b may be a chemical tank included in the substrate treating apparatus 1. Alternatively, the second supply source 19b may not be an element of the substrate treating apparatus 1. For example, the second supply source 19b may be a utility equipment located externally of the substrate treating apparatus 1. Likewise, each of the third to fifth supply sources 19c to 19e may be an element of the substrate treating apparatus 1. Alternatively, each of the third to fifth supply sources 19c to 19e may not be an element of the substrate treating apparatus 1.

The treating unit 11 may further include a cup, not shown. The cup is located inside of the casing 12. The cup is arranged around the substrate holder 13. The cup receives the liquid scattered from the substrate W held by the substrate holder 13.

Reference is made to FIG. 4. The controller 10 controls the rotation driving unit 14. The controller 10 controls the supply unit 15. The controller 10 controls the valves 18a to 18e.

### 5. Construction of First Supply Source 19a

Reference is made to FIG. 5. The first supply source 19a further produces a treatment liquid g.

A construction example of the first supply source 19a will be exemplified. The first supply source 19a is divided into a production unit 21 and a pressure feeding unit 31. The production unit 21 produces the treatment liquid g. The pressure feeding unit 31 feeds the treatment liquid g to the first supply unit 15a.

The production unit 21 includes a tank 22 and supply units 23a and 23b. The supply unit 23a supplies the sublimable substance to the tank 22. The supply unit 23b supplies the solvent to the tank 22. The sublimable substance and the solvent are mixed in the tank 22. The sublimable substance and the solvent become the treatment liquid g in the tank 22.

The tank 22 is installed under an environment of normal temperatures. The tank 22 is installed under an environment of normal pressure. Accordingly, the treatment liquid g is produced under an environment of normal temperatures. The treatment liquid g is produced under an environment of normal pressure.

Further, the production unit 21 stores the treatment liquid g. Specifically, the treatment liquid g is stored in the tank 22. Accordingly, the treatment liquid g is stored under an environment of normal temperatures. The treatment liquid g is stored under an environment of normal pressure.

The supply unit 23a includes, for example, a pipe 24a and a valve 25a. The pipe 24a is connected to the tank 22. The pipe 24a is in fluid communication with the tank 22. The valve 25a is provided on the pipe 24a. When the valve 25a opens, the supply unit 23a supplies the sublimable substance to the tank 22. When the valve 25a closes, the supply unit 23a does not supply the sublimable substance to the tank 22. Likewise, the supply unit 23b includes a pipe 24b and a valve 25b. The pipe 24b is connected to the tank 22. The pipe 24b is in fluid communication with the tank 22. The valve 25b is provided on the pipe 24b. The valve 25b controls the supply of the solvent to the tank 22.

Furthermore, the amount of sublimable substance in the tank 22 is controlled by the valve 25a. The amount of solvent in the tank 22 is controlled by the valve 25b. Therefore, the volume ratio RV of the treatment liquid g in the tank 22 is controlled by the valves 25a and 25b.

Each of the valves 25a and 25b may include, for example, a flow rate control valve. Each of the valves 25a and 25b may include, for example, a flow rate control valve and an on-off valve.

The supply unit 23a is connected to a supply source 26a. For example, the pipe 24a is connected to the supply source 26a. The supply unit 23a is in fluid communication with the supply source 26a. The supply source 26a feeds the sublimable substance to the supply unit 23a. Likewise, the supply unit 23b is connected to the supply source 26b. For example, the pipe 24b is connected to the supply source 26b. The supply unit 23b is in fluid communication with the supply source 26b. The supply source 26b feeds the solvent to the supply unit 23b.

The pressure feeding unit 31 includes a pipe 32 and a joint 33. The pipe 32 is connected to the tank 22. The pipe 32 is in fluid communication with the tank 22. The joint 33 is connected to the pipe 32. The joint 33 is also connected to the pipe 17a. The pipe 32 is connected to the pipe 17a via the joint 33. The pipe 32 is in fluid communication with the pipe 17a via the joint 33. Accordingly, the tank 22 is connected to the first supply unit 15a via the pipe 32 and the joint 33. The tank 22 is in fluid communication with the first supply unit 15a via the pipe 32 and the joint 33. Therefore, the tank 22 is connected to the nozzle 16a. The tank 22 is in fluid communication with the nozzle 16a.

The pressure feeding unit 31 further includes a pump 34 and a filter 35. The pump 34 is provided on the pipe 32. When the pump 34 actuates, the pump 34 feeds the treatment liquid g from the tank 22 to the first supply unit 15a. When the pump 34 stops actuation, the pump 34 does not feed the treatment liquid g from the tank 22 to the first supply unit 15a. The filter 35 is provided on the pipe 32. The treatment liquid g passes through the filter 35. The filter 35 filters the treatment liquid g. The filter 35 removes foreign substances from the treatment liquid g.

Reference is made to FIG. 4. The controller 10 can communicate with the first supply source 19a. The controller 10 controls the first supply source 19a. The controller 10 controls the production unit 21. The controller 10 controls the supply units 23a and 23b. The controller 10 controls the valves 25a and 25b. The controller 10 controls the pressure feeding unit 31. The controller 10 controls the pump 34.

The controller 10 has treatment liquid condition information for controlling the first supply source 19a. The treatment liquid condition information includes, for example, a target value related to the volume ratio RV of the treatment liquid g. The treatment liquid condition information is stored in advance in the storage medium of the controller 10.

### 6. Operation Example of First Supply Source 19a and Treating Unit 11

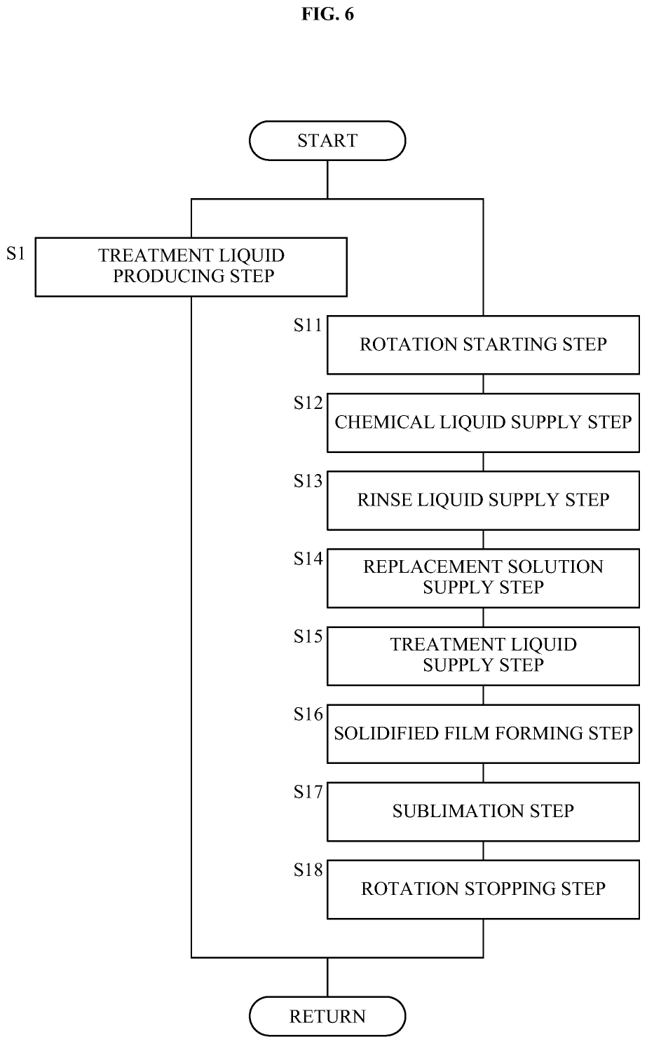

FIG. 6 is a flow chart showing procedures of a substrate treating method according to the first embodiment. The substrate treating method includes a Step S1 and Steps S11 to S18. The Step S1 is executed by the first supply source 19a. The Steps S11 to S18 are substantially executed by the treating units 11. The Step S1 is executed in parallel with the Steps S11 to S18. The first supply source 19a and the treating units 11 operate in accordance with control by the controller 10.

The following describes the Steps S1 and S11 to S18 with reference to FIG. 5 as appropriate.

### Step S1: Treatment Liquid Producing Step

In the treatment liquid producing step, the treatment liquid g is produced.

The production unit 21 produces the treatment liquid g. Specifically, the supply unit 23a supplies the sublimable substance to the tank 22. The supply unit 23b supplies the solvent to the tank 22. The sublimable substance and the solvent are mixed in the tank 22. That is, the treatment liquid g is produced in the tank 22. The treatment liquid g is stored in the tank 22.

The controller 10 controls the valves 25a and 25b. As a result, the controller 10 adjusts the volume ratio RV of the treatment liquid g in the tank 22 to the target value defined in the treatment liquid condition information.

### Step S11: Rotation Starting Step

The substrate holder 13 holds the substrate W. The substrate W is held in a substantially horizontal posture. The rotation driving unit 14 rotates the substrate holder 13. As a result, the substrate W held by the substrate holder 13 starts to rotate.

In the Steps S12 to S17 described later, the substrate W continues to rotate, for example.

### Step S12: Chemical Liquid Supply Step

In the chemical liquid supply step, the chemical liquid is supplied to the substrate W.

The second supply unit 15b supplies the chemical liquid to the substrate W held by the substrate holder 13. Specifically, the valve 18b opens. The nozzle 16b dispenses the chemical liquid. The chemical liquid is supplied onto the upper surface of the substrate W. For example, the chemical liquid etches the substrate W. For example, the chemical liquid removes a natural oxide film from the substrate W.

Thereafter, the second supply unit 15b stops the supply of the chemical liquid to the substrate W. Specifically, the valve 18b closes. The nozzle 16b stops dispensing the chemical liquid.

### Step S13: Rinse Liquid Supply Step

In the rinse liquid supply step, the rinse liquid is supplied to the substrate W.

The third supply unit 15c supplies the rinse liquid to the substrate W held by the substrate holder 13. Specifically, the valve 18c opens. The nozzle 16c dispenses the rinse liquid. The rinse liquid is supplied onto the upper surface of the substrate W. For example, the rinse liquid cleans the substrate W. For example, the rinse liquid removes the chemical liquid from the substrate W.

Thereafter, the third supply unit 15c stops the supply of the rinse liquid to the substrate W. Specifically, the valve 18c closes. The nozzle 16c stops dispensing the rinse liquid.

### Step S14: Replacement Solution Supply Step

In the replacement solution supply step, the replacement solution is supplied to the substrate W.

The fourth supply unit 15d supplies the replacement solution to the substrate W held by the substrate holder 13. Specifically, the valve 18d opens. The nozzle 16d dispenses the replacement solution. The replacement solution is supplied onto the upper surface of the substrate W. The replacement solution removes the rinse liquid from the substrate W. The replacement solution replaces the rinse liquid on the substrate W.

Thereafter, the fourth supply unit 15d stops the supply of the replacement solution to the substrate W. Specifically, the valve 18d closes. The nozzle 16d stops dispensing the replacement solution.

### Step S15: Treatment Liquid Supply Step

In the treatment liquid supply step, the treatment liquid g is supplied to the substrate W.

The pressure feeding unit 31 supplies the treatment liquid g to the first supply unit 15a. The first supply unit 15a supplies the treatment liquid g to the substrate W held by the substrate holder 13. Specifically, the pump 34 feeds the treatment liquid g from the tank 22 to the first supply unit 15a. The valve 18a opens. The nozzle 16a dispenses the treatment liquid g. The treatment liquid g is supplied onto the upper surface of the substrate W. The treatment liquid g removes the replacement solution from the substrate W. The treatment liquid g replaces the replacement solution on the substrate W.

Thereafter, the pressure feeding unit 31 stops the supply of the treatment liquid g to the first supply unit 15a. The first supply unit 15a stops the supply of the treatment liquid g to the substrate W. Specifically, the pump 34 stops. The valve 18a closes. The nozzle 16a stops dispensing the treatment liquid g.

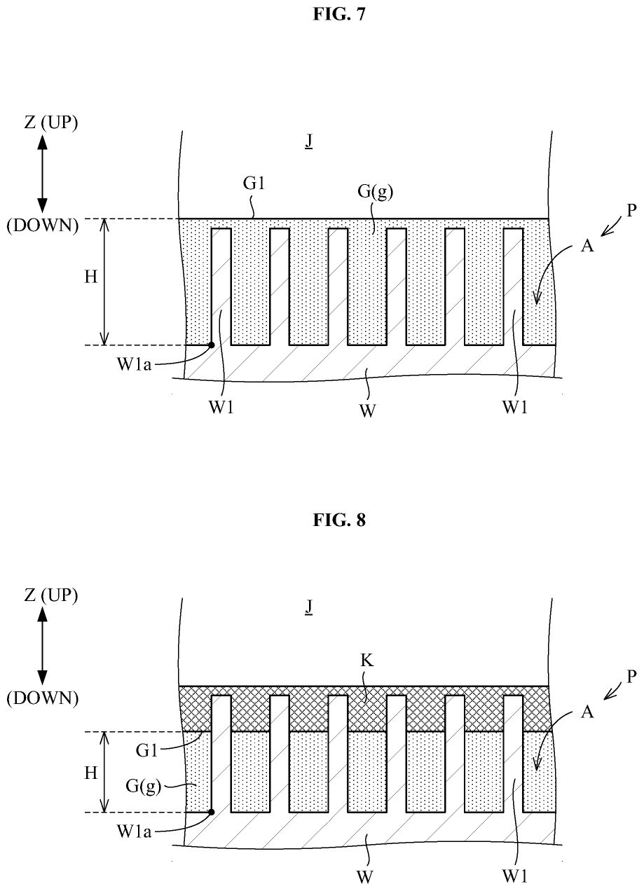

FIG. 7 is a view schematically showing the substrate W in the treatment liquid supply step. When the substrate W is held by the substrate holder 13, the pattern P is positioned on the upper surface of the substrate W. When the substrate W is held by the substrate holder 13, the pattern P is directed upward. When the substrate W is held by the substrate holder 13, the projections W1 extend upward.

The treatment liquid g on the substrate W forms a liquid film G. The liquid film G is positioned on the substrate W. The liquid film G contacts the substrate W. The liquid film G covers the substrate W. The liquid film G covers the upper surface of the substrate W.

The pattern P is entirely immersed in the liquid film G. The projections W1 are entirely immersed in the liquid film G. The recesses A are filled with the liquid film G. The recesses A are entirely filled only with the liquid film G.

The liquid film G has a top face G1. The top face G1 is positioned higher in level than the pattern P. The entire of the top face G1 is positioned higher in level than the entire of the pattern P. The top face G1 does not intersect with the pattern P. Specifically, the top face G1 is positioned higher in level than the projections W1. The entire of the top face G1 is positioned higher in level than the entire of the projections W1. The top face G1 does not intersect with the projections W1.

Here, the replacement solution has already been removed from the substrate W by the treatment liquid g. Accordingly, there is no replacement solution on the substrate W. No replacement solution remains in the recesses A.

Gas J exists above the liquid film G. The pattern P does not contact the gas J. The pattern P is not exposed to the gas J. The projections W1 do not contact the gas J. The projections W1 are not exposed to the gas J.

The gas J contacts the liquid film G. The gas J contacts the top face G1. The top face G1 corresponds to a gas-liquid interface between the liquid film G and the gas J. Therefore, the pattern P does not intersect with the gas-liquid interface between the liquid film G and the gas J. The projections W1 do not intersect with the gas-liquid interface between the liquid film G and the gas J. Accordingly, the pattern P does not receive the surface tension of the treatment liquid g. The projections W1 do not receive the surface tension of the treatment liquid g.

In the treatment liquid supply step, a height position of the top face G1 may be adjusted additionally. For example, the height position of the top face G1 may be adjusted while the nozzle 16a supplies the treatment liquid g to the substrate W. For example, the height position of the top face G1 may be adjusted after the nozzle 16a stops supplying the treatment liquid g. For example, the height position of the top face G1 may be adjusted by adjusting a rotation speed of the substrate W. For example, the height position of the top face G1 may be adjusted by adjusting a period of rotation of the substrate W.

Here, adjusting the height position of the top face G1 corresponds to adjusting thickness H of the liquid film G. The thickness H of the liquid film G is, for example, a distance in the vertical direction Z between a lower end W1a of the projection W1 and the top face G1.

### Step S16: Solidified Film Forming Step

In the solidified film forming step, the solvent evaporates from the treatment liquid g on the substrate W. In the solidified film forming step, a solidified film is formed on the substrate W. The solidified film contains the sublimable substance.

FIG. 8 is a view schematically showing the substrate W in the solidified film forming step. As described above, the solvent has a relatively high vapor pressure. At normal temperatures, the vapor pressure of the solvent is higher than the vapor pressure of the sublimable substance. Accordingly, the solvent smoothly evaporates from the treatment liquid g on the substrate W. The solvent smoothly changes from a liquid to gas.

When the solvent evaporates from the treatment liquid g on the substrate W, the solvent is removed from the treatment liquid g on the substrate W. As the solvent evaporates from the treatment liquid g on the substrate W, the amount of the solvent contained in the liquid film G decreases. As the amount of the solvent contained in the liquid film G decreases, the volume ratio RV of the liquid film G increases.

Eventually, the sublimable substance in the liquid film G starts to precipitate on the substrate W. That is, the sublimable substance changes from the solute of the treatment liquid g to the solid phase sublimable substance. The solid phase sublimable substance forms a solidified film K. The solidified film K does not contain a solvent. The solidified film K is a solid. The solidified film K is formed on the substrate W.

The liquid film G gradually changes to the solidified film K due to the precipitation of the sublimable substance. The liquid film G gradually decreases due to evaporation of the solvent and precipitation of the sublimable substance. The solidified film K gradually increases due to the precipitation of the sublimable substance.

First, the upper portion of the liquid film G is changed to the solidified film K. The solidified film K is located above the liquid film G. The solidified film K covers the top face G1 of the liquid film G.

When the solidified film K entirely covers the top face G1, the solidified film K separates the liquid film G from the gas J. The liquid film G contacts the solidified film K. The gas J contacts the solidified film K. The liquid film G does not contact the gas J. The top face G1 does not contact the gas J. The gas-liquid interface between the liquid film G and the gas J disappears.

Accordingly, the pattern P does not intersect with the gas-liquid interface. The projections W1 do not intersect with the gas-liquid interface. Therefore, the pattern P does not receive the surface tension of the treatment liquid g. The projections W1 do not receive the surface tension of the treatment liquid g.

As the solidified film K increases, the height position of the top face G1 gradually decreases. As the solidified film K increases, the thickness H of the liquid film G gradually decreases. The liquid film G decreases without applying any significant force to the projections W1. The solvent is removed from the substrate W without applying any significant force to the projections W1.

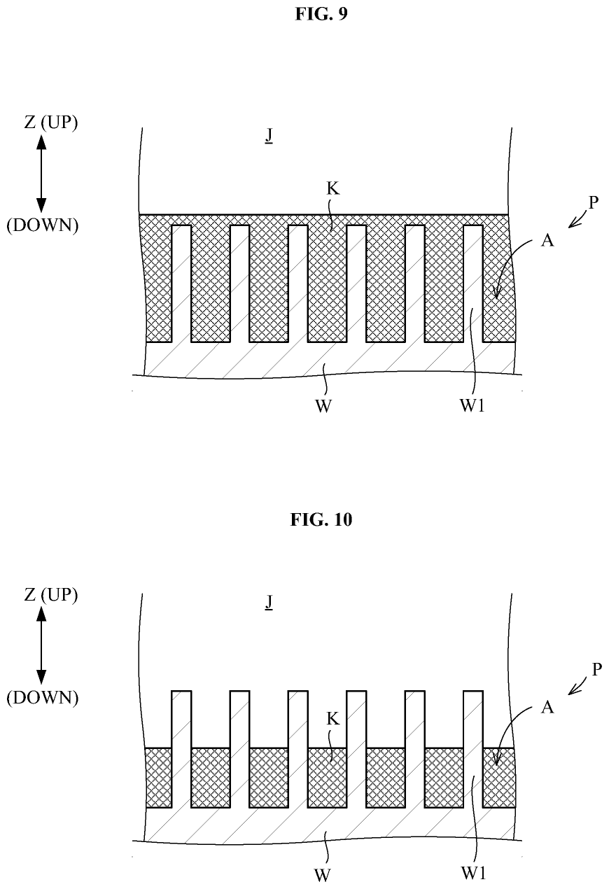

FIG. 9 is a view schematically showing the substrate W in the solidified film forming step. FIG. 9 schematically shows the substrate W when the solidified film forming step completes, for example. The liquid film G entirely disappears from the substrate W when the solidified film forming step completes. No liquid film G remains in the recesses A. The solvent entirely disappears from the substrate W. No solvent also remains in the recesses A.

When the solidified film forming step completes, only the solidified film K exists on the substrate W. The recesses A are filled with the solidified film K. The recesses A are entirely filled only with the solidified film K. The pattern P contacts the solidified film K. The solidified film K supports the pattern P. The solidified film K protects the pattern P. For example, the solidified film K prevents the pattern P from collapsing. The projections W1 contact the solidified film K. The solidified film K supports the projections W1. The solidified film K protects the projections W1. For example, the solidified film K prevents the projections W1 from collapsing.

### Step S17: Sublimation Step

In the sublimation step, the solidified film K sublimates.

The fifth supply unit 15e supplies a dry gas to the substrate W held by the substrate holder 13. Specifically, the valve 18e opens. The nozzle 16e dispenses the dry gas. The nozzle 16e blows out the dry gas to the substrate W. The dry gas is supplied onto the upper surface of the substrate W. The dry gas is supplied to the solidified film K. The solidified film K is exposed to the dry gas. As a result, the solidified film K sublimates. The solidified film K changes to gas without being a liquid. Such sublimation of the solidified film K causes the solidified film K to be removed from the substrate W.

Thereafter, the fifth supply unit 15e stops the supply of the dry gas to the solidified film K. Specifically, the valve 18e closes. The nozzle 16e stops blowing out of the dry gas.

FIG. 10 is a view schematically showing the substrate W in the sublimation step. As the solidified film K sublimates, the solidified film K gradually decreases. As the solidified film K sublimates, the solidified film K gradually becomes thinner. The pattern P starts to be exposed to the gas J. The projections W1 start to be exposed to the gas J.

When the solidified film sublimates, the solidified film K does not apply any significant force on the pattern P. The solidified film K is removed from the substrate W without applying any significant force to the pattern P. When the solidified film sublimates, the solidified film K does not apply any significant force to the projections W1. The solidified film K is removed from the substrate W without applying any significant force to the projections W1.

When the solidified film K sublimates, the solidified film K does not change to a liquid. Accordingly, in the sublimation step, the liquid is not generated on the substrate W. In the sublimation step, there is no liquid on the substrate W. In the sublimation step, there is no liquid in the recesses A. In the sublimation step, the gas-liquid interface is not generated in the vicinity of the pattern P. Therefore, in the sublimation step, the pattern P does not intersect with the gas-liquid interface. In the sublimation step, the gas-liquid interface is not generated in the vicinity of the projections W1. Therefore, in the sublimation step, the projections W1 do not intersect with the gas-liquid interface.

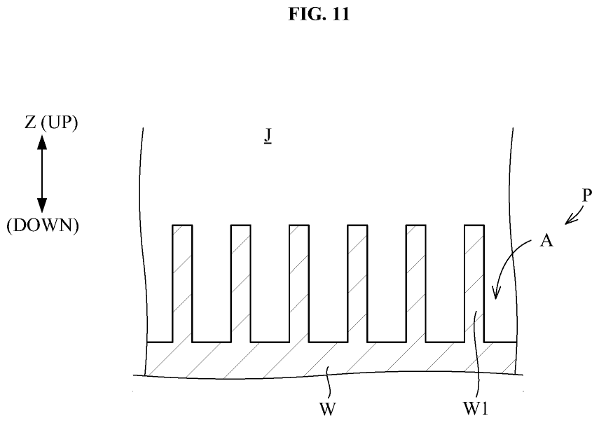

FIG. 11 is a view schematically showing the substrate W in the sublimation step. FIG. 11 schematically shows, for example, the substrate W when the sublimation step completes. The solidified film K entirely disappears from the substrate W when the sublimation step completes. There is no solidified film K on the substrate W. There is also no liquid on the substrate W. The pattern P is entirely exposed to the gas J. The projections W1 are entirely exposed to the gas J. The recesses A are entirely filled with only the gas J. The substrate W is dried.

The treatment in the treatment liquid supply step, the solidified film forming step, and the sublimation step described above are examples of the dry treatment. The treatment in the treatment liquid supply step, the solidified film forming step, and the sublimation step described above correspond to examples of use of the treatment liquid g. Examples of use of the treatment liquid g are summarized below again. The treatment liquid g is supplied to the substrate W, the solvent evaporates from the treatment liquid g on the substrate W, the solidified film K containing the sublimable substance is formed on the substrate W, and then the solidified film K sublimates. The treatment liquid g is used under an environment of normal temperatures. The treatment liquid g is used under an environment of normal pressure.

### Step S18: Rotation Stopping Step

The rotation driving unit 14 stops rotating the substrate holder 13. The substrate W held by the substrate holder 13 stops rotation. The substrate W rests. The treating units 11 complete treatment on the substrate W.

### 7. Technical Meanings of First Condition M

The following describes technical meanings of the first condition M with reference to Examples 1 to 6 and Comparative Examples 1 to 6.

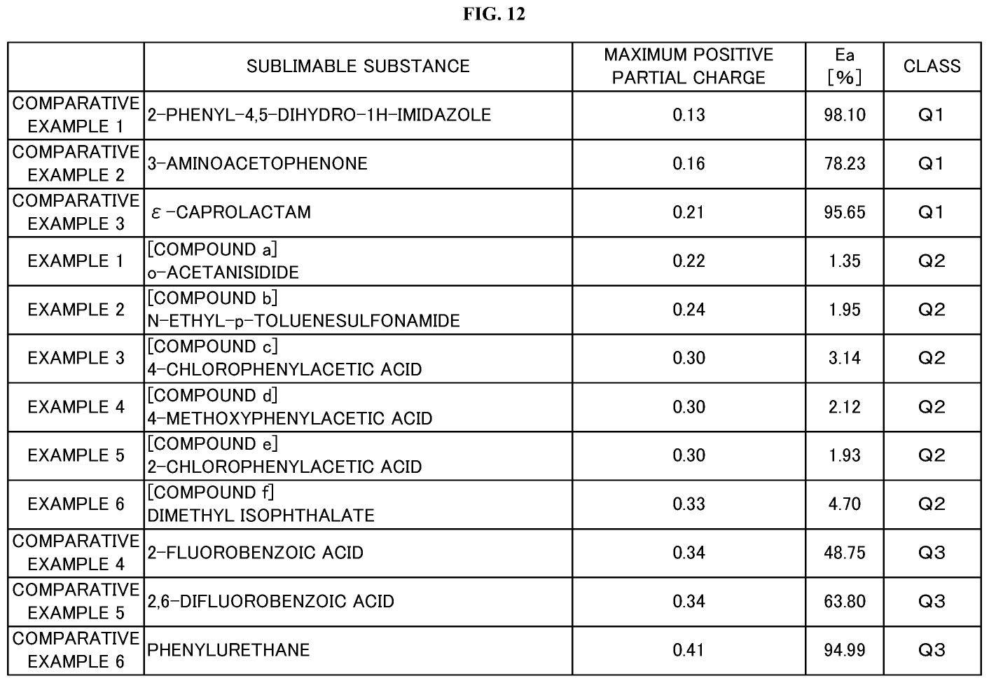

FIG. 12 is a table showing average collapse rates Ea in Examples 1 to 6 and Comparative Examples 1 to 6. The following describes conditions in Example 1. In Example 1, the substrate W is subjected to a series of treatments including the chemical liquid supply step, the rinse liquid supply step, the replacement solution supply step, the treatment liquid supply step, the solidified film forming step, and the sublimation step.

The chemical liquid used in the chemical liquid supply step is hydrofluoric acid. Hydrofluoric acid is a mixed liquid of hydrogen fluoride and water. The volume ratio of hydrogen fluoride to water is as follows.

Hydrogen fluoride:Water=1:10 (volume ratio)

The rinse liquid used in the rinse liquid supply step is deionized water.

The replacement solution used in the replacement solution supply step is isopropyl alcohol.

The treatment liquid g used in the treatment liquid supply step consists of the sublimable substance and the solvent. The sublimable substance is compound a. Specifically, the sublimable substance is o-acetanisidide. The solvent is isopropyl alcohol. The volume ratio RV of the treatment liquid g is 2.5 [Vol %].

In the solidified film forming step, the substrate W is rotated at a rotation speed of 1,500 rpm.

In the sublimation step, the dry gas is supplied to the substrate W while the substrate W is rotated at a rotation speed of 1,500 rpm.

The following describes conditions in Example 2. In Example 2, the sublimable substance is the compound b. Specifically, in Example 2, the sublimable substance is N-ethyl-p-toluenesulfonamide. The other conditions in Example 2 are the same as those in Example 1.

The following describes conditions in Example 3. In Example 3, the sublimable substance is the compound c. Specifically, in Example 3, the sublimable substance is 4-chlorophenylacetic acid. The other conditions in Example 3 are the same as those in Example 1.

The following describes conditions in Example 4. In Example 4, the sublimable substance is the compound d. Specifically, in Example 4, the sublimable substance is 4-methoxyphenylacetic acid. The other conditions in Example 4 are the same as those in Example 1.

The following describes conditions in Example 5. In Example 5, the sublimable substance is the compound e. Specifically, in Example 5, the sublimable substance is 2-chlorophenylacetic acid. The other conditions in Example 5 are the same as those in Example 1.

The following describes conditions in Example 6. In Example 6, the sublimable substance is the compound f. Specifically, in Example 6, the sublimable substance is dimethyl isophthalate. The other conditions in Example 6 are the same as those in Example 1.

The following describes conditions in Comparative Example 1. In Comparative Example 1, the sublimable substance is 2-phenyl-4,5-dihydro-1H-imidazole. The 2-phenyl-4,5-dihydro-1H-imidazole does not satisfy the first condition M. 2-Phenyl-4,5-dihydro-1H-imidazole has a maximum positive partial charge of less than 0.22. 2-Phenyl-4,5-dihydro-1H-imidazole has a maximum positive partial charge of 0.13. The other conditions in Comparative Example 1 are the same as those in Example 1.

The following describes conditions in Comparative Example 2. In Comparative Example 2, the sublimable substance is 3-aminoacetophenone. 3-aminoacetophenone is also called 1-(3-aminophenyl)ethanone. 3-Aminoacetophenone does not satisfy the first condition M. 3-Aminoacetophenone has a maximum positive partial charge of less than 0.22. 3-Aminoacetophenone has a maximum positive partial charge of 0.16. The other conditions in Comparative Example 2 are the same as those in Example 1.

The following describes conditions in Comparative Example 3. In Comparative Example 3, the sublimable substance is ε-caprolactam. ε-Caprolactam does not satisfy the first condition M. ε-Caprolactam has a maximum positive partial charge of less than 0.22. ε-Caprolactam has a maximum positive partial charge of 0.21. The other conditions in Comparative Example 3 are the same as those in Example 1.

The following describes conditions in Comparative Example 4. In Comparative Example 4, the sublimable substance is 2-fluorobenzoic acid. 2-Fluorobenzoic acid does not satisfy the first condition M. 2-Fluorobenzoic acid has a maximum positive partial charge of 0.34 or more. 2-Fluorobenzoic acid has a maximum positive partial charge of 0.34. The other conditions in Comparative Example 4 are the same as those in Example 1.

The following describes conditions in Comparative Example 5. In Comparative Example 5, the sublimable substance is 2,6-difluorobenzoic acid. 2,6-Difluorobenzoic acid does not satisfy the first condition M. 2,6-Difluorobenzoic acid has a maximum positive partial charge of 0.34 or more. 2,6-Difluorobenzoic acid has a maximum positive partial charge of 0.34. The other conditions in Comparative Example 5 are the same as those in Example 1.

The following describes conditions in Comparative Example 6. In Comparative Example 6, the sublimable substance is phenylurethane. Phenylurethane is also called ethyl N-phenylcarbamate. Phenylurethane does not satisfy the first condition M. Phenylurethane has a maximum positive partial charge of 0.34 or more. Phenylurethane has a maximum positive partial charge of 0.41. The other conditions in Comparative Example 6 are the same as those in Example 1.

The maximum positive partial charge values of the sublimable substances of Examples 1 to 6 and Comparative Examples 1 to 6 were obtained based on the chemical structures of the respective sublimable substances using MaxPartialCharge included in the RDKit. More specifically, the maximum positive partial charge values of the sublimable substances of Comparative Examples 1 to 6 was obtained based on the chemical structures of the respective sublimable substances using MaxPartialCharge included in version 2022.9.4 of the RDKit.

Substrates W treated in Examples 1 to 6 and Comparative Examples 1 to 6 were individually evaluated by the average collapse rate Ea.

The average collapse rate Ea is obtained as follows. The average collapse rate Ea is an average value of a plurality of local collapse rates Ei. The local collapse rate Ei is a collapse rate in a local area Fi. i is any natural number from 1 to NF. The number NF is the number of local areas Fi. The number NF is a natural number of 2 or more. Each local area Fi is a minute region of the substrate W. Each local area Fi is magnified 50,000 times, for example, by a scanning electron microscopy. An observer observes the pattern P in each local area Fi. The observer observes the projections W1 in each local area Fi one by one. The observer evaluates the projections W1 in each local area Fi one by one. The observer determines the projections W1 in each local area Fi one by one. Specifically, the observer determines, for each projection W1, whether or not the projection W1 has collapsed. The observer classifies each projection W1 into one of a collapsed projection W1 and a non-collapsed projection W1. Here, the number of projections W1 observed in the local area Fi is defined as NAi. The number of the collapsed projections W1 in the local area Fi is defined as NBi. The number NBi is equal to or less than the number NAi. The local collapse rate Ei is a ratio of the number NBi to the number NAi. The local collapse rate Ei is defined by, for example, the following formula.

Ei=NBi/NAi*100(%)

The average collapse rate Ea is a value obtained by dividing the sum of the local collapse rates Ei by the number NF.

In Example 1, the average collapse rate Ea was 1.35%. In Example 2, the average collapse rate Ea was 1.95%. In Example 3, the average collapse rate Ea was 3.14%. In Example 4, the average collapse rate Ea was 2.12%. In Example 5, the average collapse rate Ea was 1.93%. In Example 6, the average collapse rate Ea was 4.70%.

In Comparative Example 1, the average collapse rate Ea was 98.10%. In Comparative Example 2, the average collapse rate Ea was 78.23%. In Comparative Example 3, the average collapse rate Ea was 95.65%.

In Comparative Example 4, the average collapse rate Ea was 48.75%. In Comparative Example 5, the average collapse rate Ea was 63.80%. In Comparative Example 6, the average collapse rate Ea was 94.99%.

The following matters are found from Examples 1 to 6 and Comparative Examples 1 to 6.

The sublimable substances of Examples 1 to 6 satisfy the first condition M. Specifically, the sublimable substances of Examples 1 to 6 have a maximum positive partial charge of 0.22 or more and less than 0.34. The sublimable substances of Comparative Examples 1 to 6 do not satisfy the first condition M. Specifically, the sublimable substances of Comparative Examples 1 to 3 have a maximum positive partial charge of less than 0.22. The sublimable substances of Comparative Examples 4 to 6 have a maximum positive partial charge of 0.34 or more.

The average collapse rates Ea of Examples 1 to 6 are sufficiently smaller than the average collapse rates Ea of Comparative Examples 1 to 6. Specifically, any of the average collapse rates Ea of Examples 1 to 6 is less than 5%. Accordingly, in Examples 1 to 6, collapse of the pattern P was suitably suppressed. In other words, in Examples 1 to 6, the pattern P was suitably protected. Therefore, in Examples 1 to 6, the substrate W was appropriately dried. Specifically, in Examples 1 to 6, the substrate W was dried while the pattern P formed on the substrate W was suitably protected. Therefore, in Examples 1 to 6, treatment quality in drying the substrate W is high.

Any of the average collapse rates Ea of Comparative Examples 1 to 3 is 70% or more. Any of the average collapse rates Ea of Comparative Examples 4 to 6 is 40% or more. Accordingly, in Comparative Examples 1 to 6, the pattern P was significantly collapsed. In other words, in Comparative Examples 1 to 6, the pattern P was not protected. Therefore, in Comparative Examples 1 to 6, the substrate W was not appropriately dried. Specifically, in Comparative Examples 1 to 6, the substrate W was dried while the pattern P formed on the substrate W collapsed. Therefore, in Comparative Examples 1 to 6, treatment quality in drying the substrate W is low.

Therefore, Examples 1 to 6 and Comparative Examples 1 to 6 support that the treatment quality in drying the substrate W is significantly high when the sublimable substance satisfies the first condition M. Examples 1 to 6 and Comparative Examples 1 to 6 support that the treatment quality in drying the substrate W is significantly low when the sublimable substance does not satisfy the first condition M. In other words, Examples 1 to 6 and Comparative Examples 1 to 6 support that the substrate W is appropriately dried when the treatment liquid g containing the sublimable substance satisfying the first condition M is used. Examples 1 to 6 and Comparative Examples 1 to 6 support that the substrate W is not appropriately dried when the treatment liquid g containing the sublimable substance that does not satisfy the first condition M is used.

### 8. Assumed Mechanism

As described above, the average collapse rate Ea depends on the maximum positive partial charge of the sublimable substance. The Inventors assume the reason as follows.

The maximum positive partial charge of the sublimable substance is correlated with charge bias in one molecule of the sublimable substance. Specifically, as the maximum positive partial charge of the sublimable substance increases, the charge bias in the molecule of the sublimable substance increases. As the charge bias in the molecule of the sublimable substance increases, a Coulomb force acting between the molecules of the sublimable substance increases. That is, the molecules of the sublimable substance attract each other by a larger Coulomb force. The Coulomb force acting between the molecules of the sublimable substance affects the average collapse rate Ea.

In other words, the maximum positive partial charge of the sublimable substance is correlated with polarity of one molecule of the sublimable substance. Specifically, as the maximum positive partial charge of the sublimable substance increases, the polarity of the molecule of the sublimable substance increases. As the polarity of the molecule of the sublimable substance increases, the interaction between the molecules of the sublimable substance increases. That is, the molecules of the sublimable substance attract each other by stronger interaction. The “interaction between the molecules of the sublimable substance” is, for example, a dipole interaction. The interaction between the molecules of the sublimable substance affects the average collapse rate Ea.

According to Comparative Examples 1 to 3, when the sublimable substance has a maximum positive partial charge of less than 0.22, the average collapse rate Ea is high. The Inventors assume as follows for the mechanism for collapse of the pattern P when the sublimable substance has a maximum positive partial charge of less than 0.22.

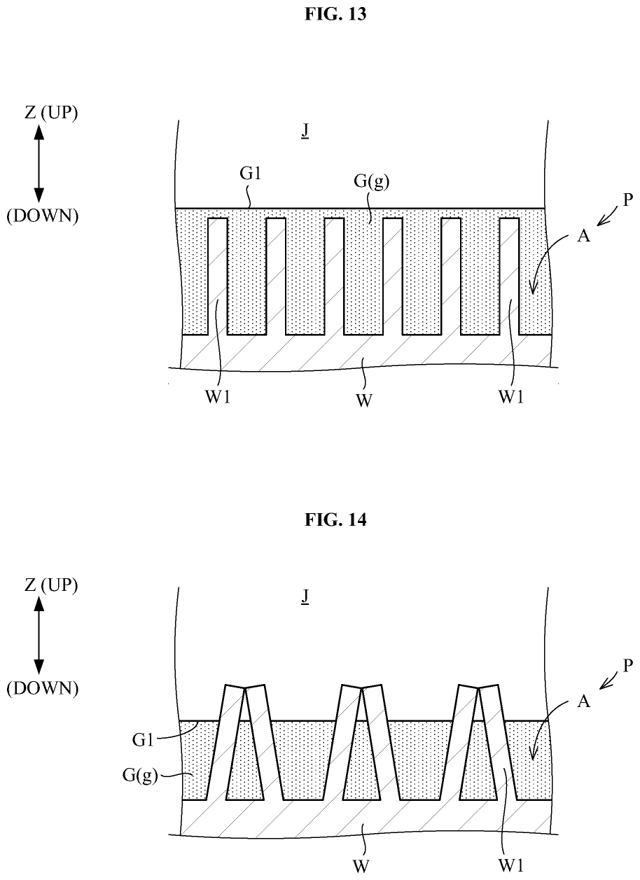

FIGS. 13 and 14 exemplarily show the mechanism for collapse of the pattern P. FIG. 13 is a view schematically showing the substrate W in the solidified film forming step. FIG. 14 is a view schematically showing the substrate W in the sublimation step.

When the sublimable substance has a maximum positive partial charge of less than 0.22, the charge bias in the molecule of the sublimable substance is too small. When the charge bias in the molecule of the sublimable substance is too small, the Coulomb force acting between the molecules of the sublimable substance is too small. When the Coulomb force acting between the molecules of the sublimable substance is too small, the solidified film K is not appropriately formed in the solidified film forming step.

In other words, when the sublimable substance has a maximum positive partial charge of less than 0.22, the polarity of the molecule of the sublimable substance is too small. When the polarity of the molecule of the sublimable substance is too small, the interaction between the molecules of the sublimable substance is too weak. When the interaction between the molecules of the sublimable substance is too weak, the solidified film K is not appropriately formed in the solidified film forming step.

Reference is made to FIG. 13. When the sublimable substance has a maximum positive partial charge of less than 0.22, the solidified film K is not appropriately formed in the solidified film forming step.

For example, in the solidified film forming step, the treatment liquid g does not change to the solidified film K. In the solidified film forming step, the solidified film K is not formed on the substrate W. Accordingly, the liquid film G still remains on the substrate W when the solidified film forming step completes. The treatment liquid g still remains on the substrate W when the solidified film forming step completes. The treatment liquid g still remains in the recesses A when the solidified film forming step completes. In the solidified film forming step, the recesses A are not entirely filled only with the solidified film K. The liquid film G still contacts the gas J. The top face G1 still contacts the gas J. The top face G1 still corresponds to the gas-liquid interface between the liquid film G and the gas J. In the solidified film forming step, the gas-liquid interface between the liquid film G and the gas J does not disappear.

Alternatively, in the solidified film forming step, the solidified film K may be formed. However, even if the solidified film K is formed in the solidified film forming step, the solidified film K is not appropriately formed. That is, the solidified film K has a defect. Although not illustrated, the density of molecules in the solidified film K is small. For example, the solidified film K is spongy. The solidified film K has many gaps. The solidified film K has many cracks. The solidified film K is porous. Accordingly, the recesses A are not entirely filled only with the solidified film K.

Further, even if the solidified film K is formed in the solidified film forming step, a part of the treatment liquid g does not change to the solidified film K. A part of the treatment liquid g still remains in the recesses A when the solidified film forming step completes.

Reference is made to FIG. 14. When the sublimable substance has a maximum positive partial charge of less than 0.22, there is the treatment liquid g on the substrate W in the sublimation step. In the sublimation step, the liquid film G on the substrate W decreases. In the sublimation step, the height position of the top face G1 of the liquid film G gradually decreases. In the sublimation step, the top face G1 corresponds to the gas-liquid interface between the liquid film G and the gas J. Accordingly, the gas-liquid interface between the liquid film G and the gas J gradually decreases. In other words, the gas-liquid interface between the treatment liquid g and the gas J gradually decreases.

Eventually, the top face G1 intersects with the pattern P. The gas-liquid interface between the liquid film G and the gas J intersects with the pattern P. The gas-liquid interface between the treatment liquid g and the gas J intersects with the pattern P. The treatment liquid g forms meniscus to the pattern P. The surface tension of the treatment liquid g acts on the pattern P. As a result, the pattern P collapses. Specifically, the top face G1 intersects with the projections W1. The gas-liquid interface between the liquid film G and the gas J intersects with the projections W1. The gas-liquid interface between the treatment liquid g and the gas J intersects with the projections W1. The treatment liquid g forms meniscus to the projections W1. The surface tension of the treatment liquid g acts on the projections W1. As a result, the projections W1 collapse.

Even if the solidified film K is formed in the solidified film forming step, there is the treatment liquid g on the substrate W in the sublimation step. Accordingly, after the solidified film K sublimates, the pattern P receives the surface tension of the treatment liquid g and collapses. After the solidified film K sublimates, the projections W1 receive the surface tension of the treatment liquid g and collapse.

According to Comparative Examples 4 to 6, when the sublimable substance has a maximum positive partial charge of 0.34 or more, the average collapse rate Ea is high. The Inventors assume as follows for the mechanism for collapse of the pattern P when the sublimable substance has a maximum positive partial charge of 0.34 or more.

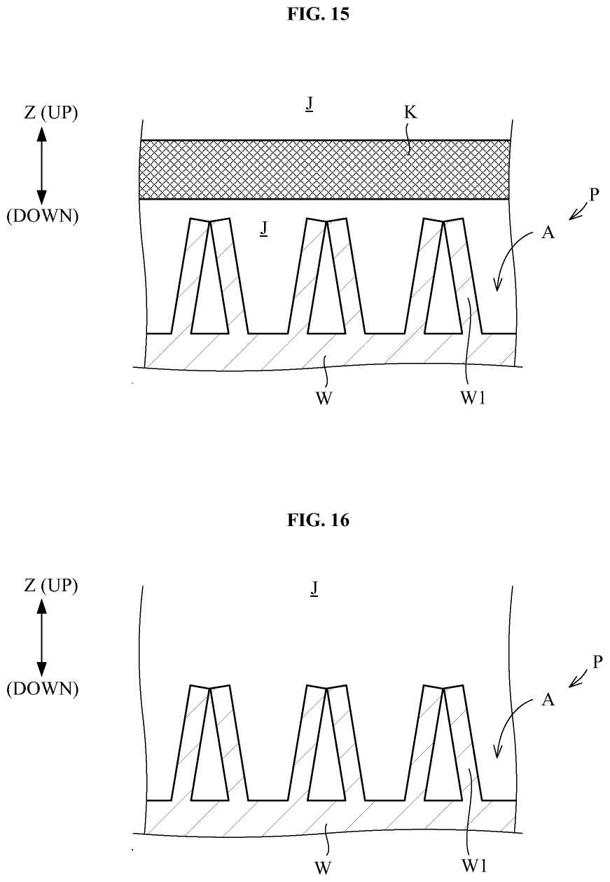

FIGS. 15 and 16 exemplarily show the mechanism for collapse of the pattern P. FIG. 15 is a view schematically showing the substrate W in the solidified film forming step. FIG. 16 is a view schematically showing the substrate W in the sublimation step.

When the sublimable substance has a maximum positive partial charge of 0.34 or more, the charge bias in the molecule of the sublimable substance is too large. When the charge bias in the molecule of the sublimable substance is too large, the Coulomb force acting between the molecules of the sublimable substance is too large. When the Coulomb force acting between the molecules of the sublimable substance is too large, the solidified film K is not appropriately formed in the solidified film forming step.

In other words, when the sublimable substance has a maximum positive partial charge of 0.34 or more, the polarity of the molecule of the sublimable substance is too large. When the polarity of the molecule of the sublimable substance is too large, the interaction between the molecules of the sublimable substance is too strong. When the interaction between the molecules of the sublimable substance is too strong, the solidified film K is not appropriately formed in the solidified film forming step.

Reference is made to FIG. 15. When the sublimable substance has a maximum positive partial charge of 0.34 or more, the solidified film K is formed in the solidified film forming step. However, in the solidified film forming step, the solidified film K is not uniformly formed. For example, the solidified film K is easily formed in a wide space, and is hardly formed in a narrow space. The space located above the pattern P is wide. Accordingly, the solidified film K is easily formed in the space located above the pattern P. On the other hand, spaces located laterally of the projections W1, that is, the recesses A are narrow. Accordingly, the solidified film K is hardly formed in the recesses A. Therefore, the solidified film K does not support the pattern P. The solidified film K does not support the projections W1. As a result, the pattern P collapses. The projections W1 collapse.

Reference is made to FIG. 16. When the sublimable substance has a maximum positive partial charge of 0.34 or more, the solidified film K sublimates in the sublimation step. After the solidified film K sublimates, the pattern P still remains collapsed. After the solidified film K sublimates, the projections W1 still remain collapsed.

According to Examples 1 to 6, when the sublimable substance has a maximum positive partial charge of 0.22 or more and less than 0.34, the average collapse rate Ea is low. The Inventors assume as follows for the mechanism for protection of the pattern P when the sublimable substance has a maximum positive partial charge of 0.22 or more and less than 0.34.

When the sublimable substance has a maximum positive partial charge of 0.22 or more and less than 0.34, the charge bias in the molecule of the sublimable substance is moderately large. When the sublimable substance has a maximum positive partial charge of 0.22 or more and less than 0.34, the charge bias in the molecule of the sublimable substance is not excessively small. When the sublimable substance has a maximum positive partial charge of 0.22 or more and less than 0.34, the charge bias in the molecule of the sublimable substance is not excessively large. When the charge bias in the molecule of the sublimable substance is moderately large, the Coulomb force acting between the molecules of the sublimable substance is moderately large. When the Coulomb force acting between the molecules of the sublimable substance is moderately large, the solidified film K is appropriately formed in the solidified film forming step.

In other words, when the sublimable substance has a maximum positive partial charge of 0.22 or more and less than 0.34, the polarity of the molecule of the sublimable substance is moderately large. When the polarity of the molecule of the sublimable substance is moderately large, the interaction between the molecules of the sublimable substance is moderately strong. When the interaction between the molecules of the sublimable substance is moderately strong, the solidified film K is appropriately formed in the solidified film forming step.

Reference is made to FIG. 9 for convenience. Specifically, the density of molecules in the solidified film K is sufficiently high. Further, the solidified film K is uniformly formed. For example, the solidified film K is also formed in a narrow space. Therefore, the recesses A are entirely filled only with the solidified film K when the solidified film forming step completes. No treatment liquid g remains in the recesses A when the solidified film forming step completes.

Reference is made to FIGS. 10 and 11 for convenience. In the sublimation step, the solidified film K sublimates. Accordingly, in the sublimation step, there is no liquid on the substrate W. In the sublimation step, there is no liquid in the recesses A. Therefore, in the sublimation step, the pattern P is not subjected to any significant force. Consequently, the pattern P does not collapse. That is, the pattern P is appropriately protected. Specifically, in the sublimation step, the projections W1 are not subjected to any significant force. Consequently, the projections W1 do not collapse. That is, the projections W1 are appropriately protected.

### 9. Effect of First Embodiment

The substrate treating method of the first embodiment is for treating the substrate W on which the pattern P is formed. The substrate treating method includes the treatment liquid supply step, the solidified film forming step, and the sublimation step. In the treatment liquid supply step, the treatment liquid g is supplied to the substrate W. The treatment liquid g contains the sublimable substance and the solvent. In the solidified film forming step, the solvent evaporates from the treatment liquid g on the substrate W. In the solidified film forming step, the solidified film K is formed on the substrate W. The solidified film K contains the sublimable substance. In the sublimation step, the solidified film K sublimates. The substrate W is dried by sublimation of the solidified film K.

Here, the sublimable substance satisfies the first condition M. Specifically, the sublimable substance has a maximum positive partial charge of 0.22 or more and less than 0.34. The maximum positive partial charge of the sublimable substance is obtained based on the chemical structure of the sublimable substance using MaxPartialCharge which is a descriptor of RDKit. Accordingly, in the solidified film forming step, the solidified film K is suitably formed on the substrate W. Furthermore, in the sublimation step, the solidified film K appropriately sublimates. That is, in the sublimation step, the substrate W is appropriately dried. Specifically, in the sublimation step, the substrate W is dried while the pattern P formed on the substrate W is suitably protected.

As described above, according to this substrate treating method, the substrate W is appropriately dried.

The sublimable substance is an organic compound. Accordingly, it is easy for the sublimable substance to satisfy the first condition M.

The sublimable substance contains a benzene ring. Accordingly, it is easy for the sublimable substance to satisfy the first condition M.

The sublimable substance contains any one of the compounds a to f. Specifically, the sublimable substance contains at least one of o-acetanisidide, N-ethyl-p-toluenesulfonamide, 4-chlorophenylacetic acid, 4-methoxyphenylacetic acid, 2-chlorophenylacetic acid, and dimethyl isophthalate. Accordingly, the sublimable substance reliably satisfies the first condition M.

The substrate treating method includes a treatment liquid producing step. In the treatment liquid producing step, the treatment liquid g is produced. Accordingly, the treatment liquid g is suitably prepared. Therefore, it is easy to use the treatment liquid g. Specifically, it is easy to supply the treatment liquid g to the substrate W in the treatment liquid supply step.

In the treatment liquid producing step, the sublimable substance and the solvent are mixed to produce the treatment liquid g. Accordingly, it is easy to produce the treatment liquid g.

In the treatment liquid producing step, the treatment liquid g is stored in the tank 22. Accordingly, it is easy to store the treatment liquid g. Therefore, it is further easier to use the treatment liquid g.

The substrate treating apparatus 1 includes the substrate holder 13 and the first supply unit 15a. The substrate holder 13 holds the substrate W. The first supply unit 15a supplies the treatment liquid g to the substrate W held by the substrate holder 13. The treatment liquid g contains the sublimable substance and the solvent.

Here, the sublimable substance satisfies the first condition M. Specifically, the sublimable substance has a maximum positive partial charge of 0.22 or more and less than 0.34. Accordingly, the solidified film K is suitably formed on the substrate W. Further, the solidified film K appropriately sublimates. That is, the substrate W is appropriately dried. Specifically, the substrate W is dried while the pattern P formed on the substrate W is suitably protected.

As described above, according to the substrate treating apparatus 1, the substrate W is appropriately dried.

The treatment liquid g is used for drying the substrate W on which the pattern P is formed. Specifically, the treatment liquid g is a dry-assisting liquid. The treatment liquid g contains the sublimable substance and the solvent.

Here, the sublimable substance satisfies the first condition M. Specifically, the sublimable substance has a maximum positive partial charge of 0.22 or more and less than 0.34. Accordingly, by supplying the treatment liquid g to the substrate W, the solidified film K is suitably formed on the substrate W. Further, the solidified film K appropriately sublimates. That is, the substrate W is appropriately dried. Specifically, the substrate W is dried while the pattern P formed on the substrate W is suitably protected.

As described above, the substrate W is appropriately dried using the treatment liquid g. The treatment liquid g is useful for drying the substrate W.

The treatment liquid g is supplied to the substrate W. The solvent evaporates from the treatment liquid g on the substrate W. The solidified film K containing the sublimable substance is formed on the substrate W. Thereafter, the solidified film K sublimates. When the treatment liquid g is used in this way, the substrate W is more appropriately dried. When the treatment liquid g is used in this way, the treatment liquid g is more useful for drying the substrate W.

### 10. Construction and Operation Example of Second Embodiment

The following describes a second embodiment with reference to the drawings. Like numerals are used to identify like components which are the same as those in the first embodiment, and the components will not particularly be described.

The second embodiment relates to a treatment liquid evaluation method for evaluating the treatment liquid g. The treatment liquid g contains the sublimable substance and the solvent. The treatment liquid g is used for drying the substrate W on which the pattern P is formed. Specifically, the treatment liquid g is used as follows. The treatment liquid g is supplied to the substrate W. The solvent evaporates from the treatment liquid g on the substrate W. The solidified film K is formed on the substrate W. The solidified film K contains the sublimable substance. Thereafter, the solidified film K sublimates.

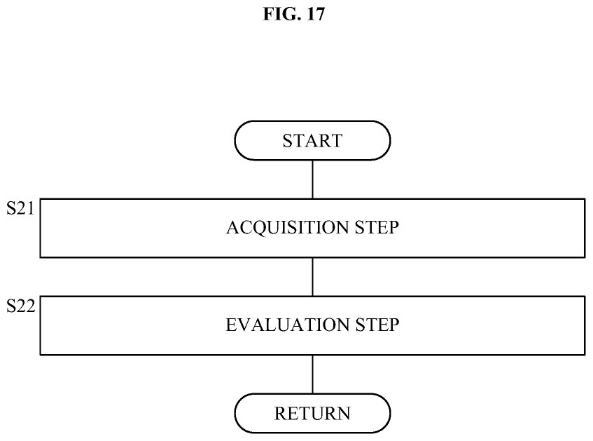

FIG. 17 is a flow chart showing procedures of the treatment liquid evaluation method of the second embodiment. The treatment liquid evaluation method includes an acquisition step and an evaluation step.

### S21: Acquisition Step

In the acquisition step, the maximum positive partial charge of the sublimable substance is acquired. The “maximum positive partial charge of the sublimable substance” is obtained based on the chemical structure of the sublimable substance using MaxPartialCharge which is a descriptor of RDKit.

### S22: Evaluation Step

In the evaluation step, the treatment liquid g is evaluated based on the maximum positive partial charge of the sublimable substance.

For example, the treatment liquid g is classified into a plurality of classes based on the maximum positive partial charge of the sublimable substance. Specifically, the treatment liquid g is classified into any one of a first class Q1, a second class Q2, and a third class Q3 based on the maximum positive partial charge of the sublimable substance.

For example, the treatment liquid g is evaluated using a threshold value. Specifically, the treatment liquid g is evaluated using a first threshold value TH1 and a second threshold value TH2. When the sublimable substance has a maximum positive partial charge of less than the first threshold value TH1, the treatment liquid g is classified into the first class Q1. When the sublimable substance has a maximum positive partial charge of equal to or more than the first threshold value TH1 and less than the second threshold value TH2, the treatment liquid g is classified into the second class Q2. When the sublimable substance has a maximum positive partial charge of equal to or more than the second threshold value TH2, the treatment liquid g is classified into the third class Q3. Here, the second threshold value TH2 is larger than the first threshold value TH1.

At least one of the first threshold value TH1 and the second threshold value TH2 may be a constant. Alternatively, at least one of the first threshold value TH1 and the second threshold value TH2 may be a variable.

Reference is made to FIG. 12. FIG. 12 shows a result of evaluating the treatment liquids g of Examples 1 to 6 and Comparative Examples 1 to 6 by the treatment liquid evaluation method described above. Here, the first threshold value TH1 is, for example, 0.22. The second threshold value TH2 is, for example, 0.34. The treatment liquids g of Comparative Examples 1 to 3 are each classified into the first class Q1. The treatment liquids g of Examples 1 to 6 are each classified into the second class Q2. The treatment liquids g of Comparative Examples 4 to 6 are each classified into the third class Q3.

### 11. Effect of Second Embodiment

The treatment liquid evaluation method is for evaluating the treatment liquid g. The treatment liquid g is used for drying the substrate W on which the pattern P is formed. Specifically, the treatment liquid g is the dry-assisting liquid. The treatment liquid g contains the sublimable substance and the solvent. The treatment liquid evaluation method includes the evaluation step. In the evaluation step, the treatment liquid g is evaluated based on the maximum positive partial charge of the sublimable substance. Therefore, the treatment liquid g is appropriately evaluated.

Specifically, in the evaluation step, the treatment liquid g is appropriately evaluated from the viewpoint of the treatment quality when the substrate W on which the pattern P is formed is dried. For example, even if the treatment liquid g is not actually supplied to the substrate W, it is easy to estimate the quality of the treatment of drying the substrate W using the treatment liquid g based on the maximum positive partial charge of the sublimable substance. For example, even if the treatment liquid g is not actually supplied to the substrate W, the treatment quality when drying the substrate W on which the pattern P is formed using the treatment liquid g is estimated based on the maximum positive partial charge of the sublimable substance. Even if the treatment liquid g is not actually supplied to the substrate W, it is easy to estimate the average collapse rate Ea based on the maximum positive partial charge of the sublimable substance. Even if the treatment liquid g is not actually supplied to the substrate W, the average collapse rate Ea is estimated based on the maximum positive partial charge of the sublimable substance. Even if the average collapse rate Ea is not actually measured, it is easy to estimate the average collapse rate Ea based on the maximum positive partial charge of the sublimable substance. Even if the average collapse rate Ea is not actually measured, the average collapse rate Ea is estimated based on the maximum positive partial charge of the sublimable substance.

As described above, according to the treatment liquid evaluation method, the treatment liquid g is appropriately evaluated. The treatment liquid evaluation method is useful for selection of the treatment liquid g. The treatment liquid evaluation method is useful for screening the treatment liquid g.

In the evaluation step, the treatment liquid g is classified into one of a plurality of classes based on the maximum positive partial charge of the sublimable substance. Therefore, in the evaluation step, the treatment liquid g is clearly evaluated.

In the evaluation step, when the treatment liquid g contains the sublimable substance satisfying the first condition M, the treatment liquid g is classified into the second class Q2. In the evaluation step, when the treatment liquid g does not contain the sublimable substance satisfying the first condition M, the treatment liquid g is not classified into the second class Q2. Therefore, it is easy to extract the treatment liquid g containing the sublimable substance satisfying the first condition M in the evaluation step.

In the evaluation step, the treatment liquid g is evaluated using the threshold value TH1 and the second threshold value TH2. Therefore, in the evaluation step, the treatment liquid g is more clearly evaluated.

The treatment liquid evaluation method further includes an acquisition step. In the acquisition step, the maximum positive partial charge of the sublimable substance is acquired. Accordingly, it is easy to evaluate the treatment liquid g based on the maximum positive partial charge of the sublimable substance in the evaluation step.

In the acquisition step, the maximum positive partial charge of the sublimable substance is obtained based on the chemical structure of the sublimable substance using MaxPartialCharge which is a descriptor of RDKit. Accordingly, in the acquisition step, the maximum positive partial charge of the sublimable substance is appropriately acquired.

### 12. Modified Embodiment

The present invention is not limited to the first and second embodiments, and can be modified as follows.
(1) In the first embodiment, the treatment liquid g is produced before the treatment liquid g is supplied to the first supply unit 15a. In the first embodiment, the first supply source 19a produces the treatment liquid g in the tank 22. However, the present invention is not limited thereto. For example, the treatment liquid g may be produced when the treatment liquid g is supplied to the first supply unit 15a. For example, the first supply source 19a may produce the treatment liquid g in a flow path for supplying the treatment liquid g to the first supply unit 15a.

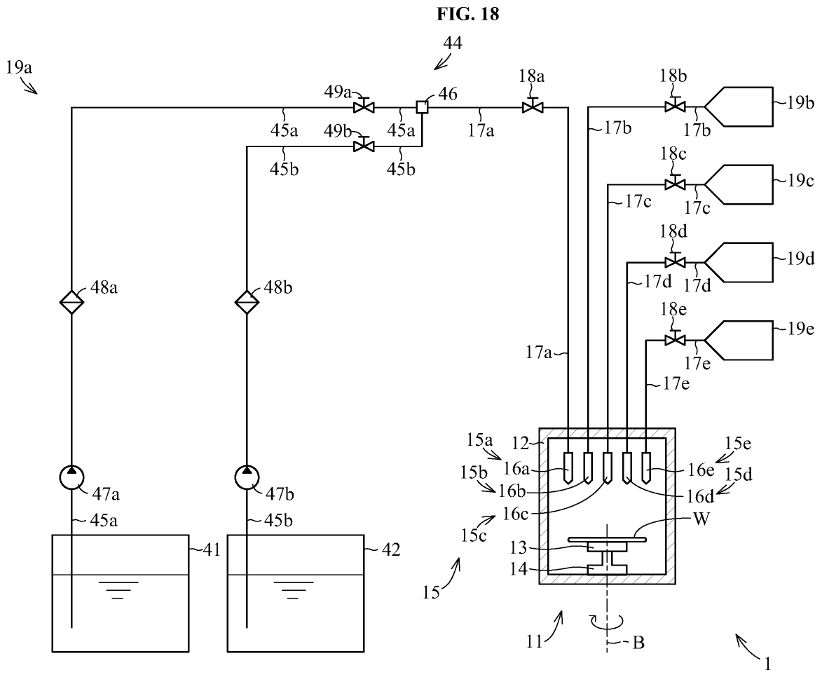

FIG. 18 is a diagram showing a construction of a treating unit 11 and a first supply source 19a according to the modified embodiment. Like numerals are used to identify like components which are the same as those in the first embodiment, and the components will not particularly be described.

The first supply source 19a includes a first tank 41 and a second tank 42. The first tank 41 stores the sublimable substance. For example, the first tank 41 may store the solvent together with the sublimable substance. The second tank 42 stores the solvent. For example, the second tank 42 stores only the solvent.

The first supply source 19a includes a mixing unit 44. The mixing unit 44 is connected to the first tank 41 and the second tank 42. The mixing unit 44 is in fluid communication with the first tank 41 and the second tank 42. The mixing unit 44 produces a treatment liquid g. The mixing unit 44 is also connected to the first supply unit 15a. The mixing unit 44 is in fluid communication with the first supply unit 15a. The mixing unit 44 supplies the treatment liquid g to the first supply unit 15a.

Specifically, the mixing unit 44 includes pipes 45a and 45b and a joint 46. The pipe 45a is connected to the first tank 41. The pipe 45a is in fluid communication with the first tank 41. The pipe 45b is connected to the second tank 42. The pipe 45b is in fluid communication with the second tank 42. The joint 46 is connected to the pipes 45a and 45b. The joint 46 is in fluid communication with the pipes 45a and 45b. The joint 46 is also connected to the pipe 17a. The joint 46 is also in fluid communication with the pipe 17a. The pipes 45a and 45b are connected to the pipe 17a via the joint 46. The pipes 45a and 45b are in fluid communication with the pipe 17a via the joint 46.

The mixing unit 44 includes pumps 47a and 47b. The pumps 47a and 47b are provided on the pipes 45a and 45b, respectively. The pump 47a feeds the sublimable substance from the first tank 41 to the joint 46 through the pipe 45a. The pump 47b feeds the solvent from the second tank 42 to the joint 46 through the pipe 45b.

The mixing unit 44 includes filters 48a and 48b. The filters 48a and 48b are provided on the pipes 45a and 45b, respectively. The sublimable substance passes through the filter 48a. The filter 48a filters the sublimable substance. The solvent passes through the filter 48b. The filter 48b filters the solvent.

The mixing unit 44 includes valves 49a and 49b. The valves 49a and 49b are provided on the pipes 45a and 45b, respectively. The valve 49a adjusts the flow rate of the sublimable substance flowing through the pipe 45a. The valve 49b adjusts the flow rate of the solvent flowing through the pipe 45b. Each of the valves 49a and 49b may include, for example, a flow rate control valve. Each of the valves 49a and 49b may include, for example, a flow rate control valve and an on-off valve.

The following describes one example of operation of the first supply source 19a in the modified embodiment. In the treatment liquid supply step, the first supply source 19a produces the treatment liquid g and feeds the treatment liquid g to the first supply unit 15a. Specifically, the valves 49a and 49b open. The pump 47a feeds the sublimable substance from the first tank 41 to the joint 46. The pump 47b feeds the solvent from the second tank 42 to the joint 46. The sublimable substance and the solvent are mixed in the joint 46. The sublimable substance and the solvent become the treatment liquid g in the joint 46. Further, the treatment liquid g flows from the joint 46 to the first supply unit 15a. The nozzle 16a dispenses the treatment liquid g.

According to this modification, it is not necessary to store the treatment liquid g before the treatment liquid g is supplied to the first supply unit 15a. Accordingly, the volume ratio RV of the treatment liquid g is accurately controlled. Therefore, the substrate W is more appropriately dried.

Furthermore, the first supply source 19a does not include the tank 22. Therefore, the structure of the first supply source 19a is suitably simplified. The first supply source 19a is suitably downsized.
(2) The substrate treating method according to the first embodiment includes a chemical liquid supply step, a rinse liquid supply step, and a replacement solution supply step. However, the present invention is not limited thereto. For example, at least one of the chemical liquid supply step, the rinse liquid supply step, and the replacement solution supply step may be omitted. For example, all of the chemical liquid supply step, the rinse liquid supply step, and the replacement solution supply step may be omitted.
(3) In the first embodiment, when the treatment liquid supply step is executed, a liquid (for example, a replacement solution) exists on the substrate W. That is, in the treatment liquid supply step, the treatment liquid g is supplied to the substrate W in a non-dried state. However, the present invention is not limited thereto. For example, when the treatment liquid supply step is executed, a liquid (for example, a replacement solution) may not exist on the substrate W. For example, in the treatment liquid supply step, the treatment liquid g may be supplied to the substrate W in a dried state.
(4) In the treatment liquid supply step of the first embodiment, the treatment liquid g removes the replacement solution from the substrate W. However, the present invention is not limited thereto. For example, in the treatment liquid supply step, the treatment liquid g may clean the substrate W. For example, in the treatment liquid supply step, the treatment liquid g may remove foreign substances adhering to the substrate W. For example, in the treatment liquid supply step, the treatment liquid g may dissolve foreign substances adhering to the substrate W. The foreign substance is, for example, a resist residue.
(5) In the solidified film forming step of the first embodiment, the dry gas is not supplied to the substrate W. However, the present invention is not limited thereto. In the solidified film forming step, the dry gas may be supplied to the substrate W. In the solidified film forming step, the dry gas may be supplied to the treatment liquid g on the substrate W. According to this modification, in the solidified film forming step, the treatment liquid g on the substrate W is exposed to the dry gas. Accordingly, in the solidified film forming step, the solvent efficiently evaporates from the treatment liquid g on the substrate W. In the solidified film forming step, the solidified film K is efficiently formed on the substrate W.
(6) In the first embodiment, for example, the pattern P on the substrate W may be formed on the substrate W before the treating unit 11 treats the substrate W. Alternatively, when the treating unit 11 treats the substrate W, the pattern P may be formed on the substrate W. The pattern P may be formed on the substrate W, for example, in the chemical liquid supply step (step S12).
(7) The first to second embodiments and each of the modified embodiments described in (1) to (6) above may be further varied as appropriate by replacing or combining their constructions with the constructions of the other modified embodiments.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating method for treating a substrate on which a pattern is formed, the substrate treating method comprising:
a treatment liquid supply step of supplying a treatment liquid containing a sublimable substance and a solvent to the substrate;
a solidified film forming step of forming a solidified film containing the sublimable substance on the substrate by evaporating the solvent from the treatment liquid on the substrate; and
a sublimation step of sublimating the solidified film, and
the sublimable substance having a maximum positive partial charge of 0.22 or more and less than 0.34.

2. The substrate treating method according to claim 1, wherein
the sublimable substance is an organic compound.

3. The substrate treating method according to claim 1, wherein
the sublimable substance contains a benzene ring.

4. A substrate treating apparatus comprising:
a substrate holder configured to hold a substrate; and
a treatment liquid supply unit configured to supply a treatment liquid containing a sublimable substance and a solvent to the substrate held by the substrate holder, and
the sublimable substance having a maximum positive partial charge of 0.22 or more and less than 0.34.

5. A treatment liquid used for drying a substrate on which a pattern is formed,
the treatment liquid containing:
a sublimable substance; and
a solvent, and
the sublimable substance having a maximum positive partial charge of 0.22 or more and less than 0.34.

6. The treatment liquid according to claim 5, wherein
the treatment liquid is supplied to the substrate, the solvent evaporates from the treatment liquid on the substrate, a solidified film containing the sublimable substance is formed on the substrate, and then the solidified film sublimates.

7. A treatment liquid evaluation method for evaluating a treatment liquid used for drying a substrate on which a pattern is formed,
the treatment liquid containing:
a sublimable substance; and
a solvent, and
the treatment liquid evaluation method including an evaluation step of evaluating the treatment liquid based on a maximum positive partial charge of the sublimable substance.

8. The treatment liquid evaluation method according to claim 7, wherein
the treatment liquid evaluation method further includes an acquisition step of acquiring the maximum positive partial charge of the sublimable substance.

9. The treatment liquid evaluation method according to claim 8, wherein
in the acquisition step, the maximum positive partial charge of the sublimable substance is obtained based on the chemical structure of the sublimable substance using MaxPartialCharge which is a descriptor of RDKit.
